(19) United States
(12) Patent Application Publication
(10) Pub. No.: US 2025/0133677 A1
(43) Pub. Date: Apr. 24, 2025

(54) ASSEMBLY STRUCTURE

(71) Applicant: FIVEGRAND INTERNATIONAL CO., LTD., New Taipei City (TW)

(72) Inventor: TING-JUI WANG, New Taipei City (TW)

(73) Assignee: FIVEGRAND INTERNATIONAL CO., LTD., New Taipei City (TW)

(21) Appl. No.: 18/915,388

(22) Filed: Oct. 15, 2024

(30) Foreign Application Priority Data
Oct. 20, 2023 (TW) 112140274
Mar. 29, 2024 (TW) 113112174

(51) Int. Cl. H05K 7/14; H05K 7/20

(52) U.S. Cl. CPC H05K 7/142; H05K 7/2049

(57) ABSTRACT

The present disclosure provides an assembly structure. The assembly structure includes a first body, a second body and an assembly portion. The assembly portion combines the first body and the second body. Accordingly, engaging connection with an engaged object or disengagement from an engaged object can be performed, so as to complete quick coupling and separation of at least two objects to achieve effects of repeated quick coupling and separation.

### CROSS-REFERENCE TO RELATED APPLICATION

This non-provisional application claims priority under 35 U.S.C. § 119 (a) on Patent Application No(s). 112140274 filed in Taiwan, R.O.C. on Oct. 20, 2023 and Patent Application No(s). 113112174 filed in Taiwan, R.O.C. on Mar. 29, 2024, the entire contents of which are hereby incorporated by reference.

### BACKGROUND OF THE INVENTION

### 1. Field of the Invention

The present disclosure relates to an assembly structure thereof, and in particular to an assembly structure for engaging connection of at least two objects to achieve effects of quick coupling and easy removal.

### 2. Description of the Related Art

In general, when two objects are to be coupled, lock connection is usually performed using a screw to fix the two objects in a manner that they do not separate easily, thereby ensuring stable coupling between these two objects without the two separating from each other easily.

In the conventional fixing means above, although two objects can be fixed and coupled in a form that is not easily separated, in addition to unhandy assembly, the two objects may not be easily removed or separated due to the fixed coupling means using the screw.

### BRIEF SUMMARY OF THE INVENTION

On the basis of at least one embodiment of the present disclosure, the present disclosure provides an assembly structure and an assembly method thereof. Engaging connection with an engaged object or disengagement from an engaged object can be performed, so as to complete quick coupling and separation of at least two objects to achieve effects of repeated quick coupling and separation

To achieve the above and other objects, the present disclosure provides an assembly structure and an assembly method thereof. The assembly structure includes a first body a second body and an assembly portion. The assembly portion combines the first body and the second body.

The present disclosure further provides an assembly method of an assembly structure including a first body, a second body and an assembly portion. The assembly portion includes an insert portion and a press portion. The insert portion is disposed at the first body, the press portion is disposed at an outer edge of one end of the second body, and the second body passes through the insert portion and is pressed at an inner edge of the insert portion by the press portion so as to combine the first body and the second body.

The present disclosure further provides an assembly method of an assembly structure including a first body, a second body and an assembly portion. The assembly portion passes through the first body and the second body, and the assembly portion is pressed by a mold for expansion connection and combination, or wherein the assembly portion is an elastic body and is squeezed into the first body so as to be elastically assembled with the second body.

The present disclosure further provides another assembly method of an assembly structure including a first body, a second body and an assembly portion. The assembly portion is an elastic body, and is squeezed into the first body so as to be elastically bolted with the second body.

The present disclosure further provides another assembly method of an assembly structure including a first body, at least two second bodies and at least two assembly portions. Each of the second bodies is assembled at the first body by one assembly portion, an elastic component is provided between each of the assembly portions and each of the second bodies, and each of the elastic component is pulled close to each of the second bodies so as to reduce a height of the assembly structure.

The present disclosure further provides an assembly method of an assembly structure including a first body, a second body and an assembly portion. The first body and the second body are combined by the assembly portion, or an elastic component is provided between the assembly portion and the second body, or the elastic component pulls close the first body so as to reduce a height of the assembly structure.

The present disclosure further provides another assembly method of an assembly structure including a first body, at least two second bodies and at least two assembly portions. Each of the second bodies is assembled at the first body by an assembly portion, the first body is provided with at least two accommodating spaces, and the second bodies are respectively disposed in the accommodating spaces so as to reduce a combination height of the each of the second bodies.

The present disclosure further provides another assembly method of an assembly structure including a first body, a second body and an assembly portion. The first body and the second body are combined by the assembly portion, the first body or the second body is provided with an accommodating space, and the first body or the second body is disposed in the accommodating space so as to reduce a height of the assembly structure.

The present disclosure further provides an assembly method of an assembly structure including at least one first body, at least one second body and at least one assembly portion. The first body and the second body are combined by the assembly portion, the first body or the second body is disposed at a fixing body, the fixing body is assembled at an object, and the first body or the second body and the fixing body are riveted, expansion connected, locked, welded, engaged or formed integrally.

The present disclosure further provides an assembly method of an assembly structure including at least one first body, at least one second body, at least one assembly portion and at least one elastic component. The first body and the second body are combined by the assembly portion, two ends of the elastic component respectively abut against the assembly portion and the second body so as to reduce a height of the second body by the elastic component, or for the first body or the second body to be rotated so as to reduce a height of the first body or the second body.

The present disclosure further provides another assembly method of an assembly structure, the assembly portion is vertically assembled or horizontally assembled at the first body or the second body, and an elastic space, a shockproof space, a height adjustment space or a height abutment space is defined between the first body, the second body or the assembly portion by an elastic component or a shockproof component.

The present disclosure further provides another assembly method of an assembly structure, the assembly portion is for being pressed by a mold for expansion connection and combination, or wherein the assembly portion is an elastic body, or the assembly portion is for being squeezed in for elastic assembly, or wherein the assembly portion has an elastic squeeze space for the assembly portion to appear as a withdrawn condition when squeezed in, or wherein the assembly portion is for being pressed by a mold and is pressed and deformed, for the assembly portion to abut against, press against or support against the first body or the second body, and for a floating amount between the assembly portion and the first body or the second body be filled, reduced or reset to zero, or for a floating amount between the first body and the second body to be filled, reduced or reset to zero.

The present disclosure further provides another assembly method of an assembly structure, the first body and the second body have connecting portions for combining with each other, wherein the connecting portions have a floating amount in between, and the assembly portion is pressed and deformed, for the assembly portion to abut against, press against or support the connecting portions for the floating amount to be filled, reduced or reset to zero.

The present disclosure further provides another assembly method of an assembly structure, the first body has a block portion, and the block portion is for blocking the assembly portion to limit a position of the first body that is rotated, or to limit the first body to be located at a position at 90 degrees or close to 90 degrees relative to the second body, or to limit the first body to be located a position at 15 degrees to 150 degrees relative to the second body, or to limit an angle of the first body relative to the second body.

The present disclosure further provides another assembly method of an assembly structure including a first body, a second body and an assembly portion. The assembly portion combines the first body and the second body, and the first body has a rotating portion or a moving portion, or the rotating portion or the moving portion is a structure of a sloped surface, an arc surface, a curved surface or a non-right-angle surface and abuts against the second body and the assembly portion by an elastic component, for the rotating portion or the moving portion to be driven elastically or rotate or move so as to reduce a height of the first body.

The present disclosure further provides another assembly method of an assembly structure including a first body, a second body and an assembly portion. The assembly portion combines the first body and the second body, the first body has a limiting portion, the limiting portion is for limiting a position of the first body that is rotated, and the second body has an elastic component which for abutting against the limiting portion, or the second body has an elastic component which is for abutting against an intermediator at the limiting portion so as to reduce a height of the first body.

The present disclosure further provides another assembly method of an assembly structure including a first body, a second body and an assembly portion. The assembly portion combines the first body and the second body, the assembly structure is for being assembled at a heat dissipater, or the assembly structure is a heat dissipater, or the heat dissipater is for dissipating heat of a heat generator, or the heat dissipater has a passage for a cooling fluid to flow through for heat dissipation, or the heat dissipater has an engaging body for being engagingly connected at an object by an engaging body, and the object is provided with a heat dissipater, a printed circuit board, a metal body or a non-metal body.

The present disclosure further provides another assembly method of an assembly structure including a first body, a second body and an assembly portion. The assembly portion combines the first body and the second body, and the second body is a heat dissipater, or the second body and a heat dissipater are formed integrally, or the second body is disposed at a heat dissipater.

The present disclosure further provides another assembly method of an assembly structure including a first body, a second body and an assembly portion. The assembly portion combines the first body and the second body, and the second body has an elastic component which is for abutting against the first body to reduce a height of the first body, or the second body has an elastic component which is for abutting against an intermediator, for the intermediator to abut against the first body to reduce a height of the first body.

The present disclosure further provides another assembly method of an assembly structure including a first body, a second body and an assembly portion. The assembly portion combines the first body and the second body, the second body is has a setup portion for disposing or installing the assembly portion, or the setup portion is a movement space, and the assembly portion moves in the movement space.

Optionally, the first body has a block portion, or the block portion is for blocking the assembly portion to limit a position of the first body, or to limit a position of the first body to be located at a position at 90 degrees or close to 90 degrees relative to the second body, or to limit the first body located to be located at a position at 15 degrees to 150 degrees relative to the second body, or to limit an angle of the first body located at the second body.

Optionally, the first body is provided with an insert portion, and the second body passes through the insert portion.

Optionally, the assembly portion includes an insert portion and a press portion. The insert portion is disposed at the first body, the press portion is disposed at an outer edge of one end of the second body, and the second body passes through the insert portion and is pressed at an inner edge of the insert portion by the press portion.

Optionally, the second body or the second body is provided with an engaging portion.

Optionally, the first body is provided with an insert portion and a setup portion, and the second body is provided with an installation portion. The second body passes through the insert portion and corresponds the installation portion with the setup portion, and the assembly portion passes through the installation portion and is assembled with the setup portion, for the first body and the second body to be combined with each other.

Optionally, the assembly portion is a bolt or an elastic body.

Optionally, the first body and the second body are plural in quantity, and are combined with each other by connecting portions and fixed with each other by the assembly portion.

Optionally, each of the connecting portions can be cylindrical or a through hole.

Optionally, the assembly portions respectively pass through two first bodies, and are pressed by a mold for expansion connection and combination.

Optionally, each of the assembly portions is an elastic body, and the assembly portions are respectively squeezed into two second bodies for elastic bolting or assembly.

Optionally, each of the assembly portions has an elastic squeeze space for the assembly portions to appear as a withdrawn condition when squeezed into two second bodies, or wherein the assembly portion is for being pressed by a mold and is thus pressed and deformed, for the assembly portion to abut against, press against or support the first body or the second body, and for a floating amount between the assembly portion and the first body or the second body be filled, reduced or reset to zero, or for a floating amount between the first body and the second body to be filled, reduced or reset to zero.

Optionally, the assembly portion, the first body and the second body are combined with each other by connecting portions, the connecting portions have a floating amount in between, and each of the assembly portions is pressed and deformed, for each of the assembly portions to abut against, press against or supports each of the connecting portions for each of the floating amounts to be filled, reduced or reset to zero.

Optionally, the assembly portion and the first body have a floating amount in between, or the assembly portion and the second body have a floating amount in between, or the first body and the second body have a floating amount in between, and the floating amount is between 0.0001 mm and 5 mm.

Optionally, each of the assembly portions and each of the connecting portions can be formed of a metal material or a deformable material.

Optionally, each of the assembly portions expands or deforms, or each of the floating amount is filled, reduce or reset to zero, or each of the assembly portions expands, deforms or shortens, or each of the floating amounts is filled, reduced or reset to zero.

Optionally, the assembly structure is applied to a data center, a server or a storage device.

Optionally, the first body, the second body or the assembly portion is an engaging body, a metal structured body, a rivet, a welding body, an expansion connection body, a lock, a handle, a bolt, an elastic body, a rod, an expansion connection body, a rivet, a metal body, a shockproof body, an elastic body, a plastic body or is formed of a deformable material, or the assembly portion and the first body or the second body are formed integrally.

Optionally, each of the assembly portions is formed of a metal material, or each of the assembly portions is deformable or expandable material when pressed.

Optionally, at least two second bodies are further included. Each of the second bodies is combined at the first body by an assembly portion, and an elastic component is provided between each of the second bodies and each of the second bodies, or wherein an elastic component is provided between one of the assembly portions and one of the second bodies.

Optionally, the first body and the second body are combined into a handle, a pulling structure or an engaging body, and each of the elastic components pulls close each of the second bodies to reduce a height of each of the second bodies, or to reduce a height of the first body, or for the second body to elastically withdraw so as to reduce a height of the assembly structure.

Optionally, each of the second bodies is combined at an object by locking, riveting, engagement connection, expansion connection or welding, or is formed integrally with an object, and the object is a metal body, a plastic body, a computer, a track body, a casing, a circuit board, a heat dissipater, a chip, a track, a connector, a fan, a casing, an M.2 card, an E1.S card, an E3.S card, a storage device, a server or a data center.

Optionally, the first body or the second body is provided with an accommodating space, and the first body or the second body is disposed in the accommodating space so as to reduce a height of the assembly structure.

Optionally, each accommodating space is an opening, a step, a recess, slot, a notch or a through hole.

Optionally, one end of each of the elastic components abuts against each of the second bodies, and the other end of each of the elastic components abuts against each of the assembly portions, for reducing a height of each of the two second bodies, or for each of the second bodes to elastically withdraw, or for reducing a height of the assembly structure.

Optionally, the first body or the second body is disposed at a fixing body, the fixing body is assembled at an object, and the first body or the second body and the fixing body are riveted, expansion connected, locked, welded, engagingly connected or formed integrally.

Optionally, the fixing body is combined at the object by locking, riveting, engagement connection, expansion connection or welding, the object is a metal body, a plastic body, a computer, a circuit board, a heat dissipater, a chip, a track, a connector, a fan, a casing, an M.2 card, an E1.S card, an E3.S card, a storage device, a server or a data center, or the object is a heat dissipater, and the object is disposed at a heat generator to perform heat dissipation, the heat generator is a chip or a memory, or the object is a printed circuit board (PCB) or a casing for placing a chip or a memory, or the object can be moved or removed during an operation of a chip.

Optionally, the first body or the second body is combined at the object by locking, riveting, engagement connection, expansion connection or welding or is formed integrally with the object, or the object is a metal body, a plastic body, a computer, a circuit board, a heat dissipater, a chip, a track, a connector, a fan, a casing, an M.2 card, an E1.S card, an E3.S card, a storage device, a server or a data center, or the object is a heat dissipater, or the object is disposed at a heat generator to perform heat dissipation, the heat generator is a chip or a memory, or the object is a printed circuit board (PCB) or a casing for placing a chip or a memory, or the object can be moved or removed during an operation of a chip.

Optionally, multiple first bodies, multiple second bodies and multiple assembly portions can be further included. Each of the first bodies and each of the second bodies are combined by each of the assembly portions. An elastic component is provided between each of the second bodies and each of the assembly portions, and two ends of each of the elastic components respectively abut against each of the assembly portions and each of the second bodies, for each of the elastic components to elastically reduce a height of each of the second bodies, or for each of the first bodies or each of the second bodies to rotate so as to reduce a height of each of the first bodies or each of the second bodies.

Optionally, the second body and the assembly portion have an elastic component in between, and two ends of the elastic component elastically abut against the assembly portion and the first body to elastic reduce a height of the first body, or for the first body to rotate to reduce a height of the first body, or the first body has a block portion, and the block portion is for blocking the assembly portion to limit a position of the first body that is rotated, or to limit the first body to be located at a position at 90 degrees or close to 90 degrees relative to the second body, or to limit the first body to be located at 15 degrees to 150 degrees relative to the second body, or to limit an angle of the first body at the second body.

Optionally, the first body and the assembly portion are combined into a module disposed at the second body, and two ends of an elastic component respectively abut against the first body and the second body for the assembly portion to be engaged into another object.

Optionally, the first body and the assembly portion are combined into a module and are disposed at a fixing body, and two ends of an elastic component respectively abut against the first body and the fixing body for the second body to be engaged into another object.

Optionally, numbers of the first body, the second body and the assembly portion are respectively one, two or three, for the first body, the second body and the assembly portion to be formed integrally or to be combined into a module.

Optionally, the assembly portion is vertically assembled or horizontally assembled at the first body or the second body, and an elastic space, a shockproof space, a height adjustment space or a height abutment space is defined between the first body, the second body or the assembly portion by an elastic component or a shockproof component.

Optionally, an elastic space, a shockproof space, a height adjustment space or a height abutment space is defined between the first body, the second body and the assembly portion by an elastic component or a shockproof component, or the first body and the second body are respectively assembled at two objects for an elastic space, a shockproof space, a height adjustment space or a height abutment space to be present between the individual objects, to serve as buffering, position adjustment, height adjustment or height abutment between the individual objects.

Optionally, the assembly portion is vertically assembled or horizontally assembled at the first body or the second body, an elastic space, a shockproof space, a height adjustment space or a height abutment space is defined between the first body, the second body or the assembly portion by an elastic component or a shockproof component, and the elastic component or the shockproof component causes the first body and the second body to be located at an interval position, a pulled-close position, a height adjustment position or a height abutment position.

Optionally, the first body or the second body is provided with an anti-rotation portion. The anti-rotation portion is for preventing rotation relative to an object, or the anti-rotation portion is for preventing rotation when locked at an object, or the anti-rotation portion is for preventing rotation when locked at an object to further prevent the first body and the second body from a reduced or loosened screw locking force caused by locking torque, or each of the first body and the second body is provided with a corresponding anti-rotation portion for preventing rotation.

Optionally, the first body or the second body is locked, riveted, expansion connected, welded, adhered or engagingly connected at an object or two objects.

Optionally, the assembly portion is an extension structure of the first body, and is for mutually interfering, engaging or assembling with an extension structure of the second body, and the assembly portion is an extension structure integrally formed with the first body and is for mutually interfering, engaging or assembling with the extension structure of the second body.

Optionally, the second body is provided with an assembly portion, the assembly portion is an extension structure of the second body and is for mutually interfering, engaging or assembling with an extension structure of the first body, and the assembly portion is an extension structure integrally formed with the second body and is for mutually interfering, engaging or assembling with the extension structure of the first body.

Optionally, the first body and the second body can be concurrently or separately assembled at a metal plate, a circuit board or a plastic plate.

Optionally, the first body has a head and a neck for being engagingly connected at an object, or the head passes through an entry portion of the object and is engaged at an engagement receiving portion of the object by the neck, or the first body has a head and a neck for being engagingly connected at an object, and the first body and the second body or the assembly portion have an elastic component or a shockproof component in between, or the first body has a head and a neck for being engagingly connected at an object, and the first body and the second body or the assembly portion have an elastic component or a shockproof component in between to define an elastic space, a shockproof space, a height adjustment space or a height abutment space.

Optionally, the first body has a shoulder, and the shoulder is for blocking or receiving a pressure for a material of the object to flow into or enter a material entry portion of an combining portion of the first body, or the shoulder is for blocking or being pressed for a material of an object to be fittingly connected at a combining portion of the first body or for the first body to be expansion connected at the object.

Optionally, the first body, the second body or the object is formed of a metal material, or the first body is formed of a thermal treated metal material or plastic material, or a hardness of the first body is greater than that of the object, or material of the object enters or flows into a material entry portion of the first body when the first body is riveted and pressed at the object.

Optionally, the assembly portion is riveted or pressed at the first body or the second body for assembly, and a width of the assembly portion is greater than that of an insert portion of the first body so as to interfere with, squeeze or abut against a material for assembly, or the insert portion has a guide portion which guides the assembly portion for assembly.

Optionally, the insert portion has a guide portion which guides the assembly portion for assembly.

Optionally, the width of the assembly portion is 0.000001 mm to 5 mm.

Optionally, the assembly portion passes through the first body and enters the second body for expansion connection and assembly, wherein an elastic component is included, and two ends of the elastic component respectively abut against the second body and the assembly portion, or the assembly portion passes through the first body and enters the second body for expansion connection and stopping at a stop member, wherein an elastic component is included, and two ends of the elastic component respectively abut against the second body and the stop member, or the assembly portion passes through the second body and enters the first body for expansion connection and stopping at a stop member, or the assembly portion passes through the second body and enters the first body for expansion connection and assembly.

Optionally, the assembly portion has an engaging portion for engaging connecting with an object, or the assembly portion has an engaging portion, the engaging portion is driven by movement of the first body for the engaging portion to be engagingly connected with an engaged object or be disengaged from the engaged object, or the assembly portion has an engaging portion for being driven by rotation of the first body for the engaging portion to be engagingly connected with an engaged object or be disengaged from the engaged object, or the assembly portion has an engaging portion for being driven by rotation of the first body at a first height or a second height for the engaging portion to be engagingly connected with an engaged object or be disengaged from the engaged object, the assembly portion has an engaging portion for being driven by the first body at different positions at a first height or a second height for the engaging portion to be engagingly connected with an engaged object or be disengaged from the engaged object.

Optionally, the assembly portion has an engaging portion for being driven by movement of the first body and for being engagingly connected with an engaged object or be disengaged from the engaged object, or wherein a fixing body to which the second body is assembled is for being combined at an object, or the engaging portion is disengaged from a casing, or the first body or the second body is pulled or operated to remove a memory or an object from a connector, or the engaging portion is engagingly connected at a casing, or the first body or the second body is pulled or operated to plug/unplug a memory or an object into/from a connector.

Optionally, the assembly portion has an engaging portion for being driven by movement of the first body and for being engagingly connected with an engaged object or be disengaged from the engaged object, or wherein a fixing body to which the second body is assembled is for being combined at an object, or the engaging portion is disengaged from a casing, or the first body or the second body is pulled or operated to insert a memory or an object into a connector, or the engaging portion is engaged at a casing, or the first body or the second body is pulled or operated to hot-plug a memory or an object into a connector.

Optionally, the first body has a press portion and a pull portion, for the press portion to be first pressed and rotated and the pull portion to be pulled.

Optionally, at least one first body, two second bodies and three assembly portions combined with each other are included, or at least one first body, two second bodies and three assembly portions are included, wherein each of the first body, two second bodies and two assembly portions has a through hole for mutually combining with the individual assembly portions, or at least one first body, two second bodies and one assembly portions are included, wherein each of the first body and the two second bodies has a through hole for mutually combining with the assembly portion, or at least one first body, two second bodies and one assembly portion are included, wherein each of the two second bodies has a through hole for mutually combining with the assembly portion.

Optionally, the second body has a stop portion for limiting a position of the first body, or the second body has a stop portion for limiting an angle of the first body relative to the second body, or the second body has a stop portion for limiting an angle of the first body to be 15 degrees to 345 degrees relative to the second body.

Optionally, the first body has a rotating portion or a moving portion, or the rotating portion or the moving portion is a structure of a sloped surface, an arc surface, a curved surface or a non-right-angle surface and abuts against the second body and the assembly portion by an elastic component, for the rotating portion or the moving portion to be elastically driven to rotate or move so as to reduce a height of the first body.

Optionally, the first body has a limiting portion, the limiting portion is for limiting a position of the first body that is rotated, and the second body has an elastic component which for abutting against the limiting portion, or the second body has an elastic component which is for abutting against an intermediator at the limiting portion so as to reduce a height of the first body.

Optionally, the assembly structure is for being assembled at a heat dissipater, or the assembly structure is a heat dissipater, or the heat dissipater is for dissipating heat of a heat generator, or the heat dissipater has a passage for a cooling fluid to flow through for heat dissipation, or the heat dissipater has an engaging body for being engagingly connected at an object by an engaging body, and the object is provided with a heat dissipater, a printed circuit board, a metal body or a non-metal body.

Optionally, the second body is a heat dissipater, or the second body and a heat dissipater are formed integrally, or the second body is disposed at a heat dissipater.

Optionally, the second body has an elastic component which is for abutting against the first body to reduce a height of the first body, or the second body has an elastic component which is for abutting against an intermediator, for the intermediator to abut against the first body to reduce a height of the first body.

Optionally, the second body is has a setup portion for disposing or installing the assembly portion, or the setup portion is a movement space, and the assembly portion moves in the movement space.

Optionally, the first body and the second body or the assembly portion have an elastic component or a shockproof element in between, or the first body and the second body or the assembly portion have an elastic component or a shockproof element in between to define an elastic space, a shockproof space, a height adjustment space or a height abutment space, or the first body is assembled at an object, and the second body is assembled at an object, or a distance between the two objects is greater the first body and the second body, or the two objects are not horizontal, or wherein one of the objects is non-planar or has a non-uniform thickness, or the two objects are non-planar and have non-uniform thicknesses, or a distance between the two objects is less than an accumulated height of the first body, the second body and a distance of travel of the elastic component or the shockproof element, for the first body, the second body, the assembly portion and the elastic component or the shockproof element to perform elastic ascending or elastic descending, or for the two objects to be assembled, or for providing shockproofness for the two objects or shockproofness for one of the objects.

The present disclosure further provides another assembly method of an assembly structure including a first body, a second body and an assembly portion. The assembly portion has an engaging portion for engaging connecting with an object, or the assembly portion has an engaging portion driven by movement of the first body for the engaging portion to be engagingly connected with an engaged object or be disengaged from the engaged object, or the assembly portion has an engaging portion for being driven by rotation of the first body for the engaging portion to be engagingly connected with an engaged object or be disengaged from the engaged object, or the assembly portion has an engaging portion for being driven by rotation of the first body at a first height or a second height for the engaging portion to be engagingly connected with an engaged object or be disengaged from the engaged object, the assembly portion has an engaging portion for being driven by the first body at different positions at a first height or a second height for the engaging portion to be engagingly connected with an engaged object or be disengaged from the engaged object.

The present disclosure further provides another assembly method of an assembly structure including a first body, a second body and an assembly portion. The assembly portion has an engaging portion for being driven by movement of the first body and for being engagingly connected with an engaged object or be disengaged from the engaged object, or wherein a fixing body to which the second body is assembled is for being combined at an object, or the engaging portion is disengaged from a casing, or the first body or the second body is pulled or operated to remove a memory or an object from a connector, or the engaging portion is engagingly connected at a casing, or the first body or the second body is pulled or operated to plug/unplug a memory or an object into/from a connector.

The present disclosure further provides another assembly method of an assembly structure including a first body, a second body and an assembly portion. The assembly portion has an engaging portion which is for being driven by movement of the first body and for being engagingly connected with an engaged object or be disengaged from the engaged object, or wherein a fixing body to which the second body is assembled is for being combined at an object, or the engaging portion is disengaged from a casing, or the first body or the second body is pulled or operated to hot-plug a memory or an object into a connector, or the engaging portion is engagingly connected at a casing, or the first body or the second body is pulled or operated to hot-plug a memory or an object into a connector.

The present disclosure further provides another assembly method of an assembly structure including a first body, a second body and an assembly portion. The first body and the second body are combined by the assembly portion, wherein the first body has a press portion and a pull portion, for the press portion to be first pressed and rotated and then the pull portion to be pulled.

The present disclosure further provides another assembly method of an assembly structure including a first body, a second body and an assembly portion. The first body and the second body are combined by the assembly portion, wherein the second body has a stop portion for limiting a position of the first body, or the second body has a stop portion for limiting an angle of the first body relative to the second body, or the second body has a stop portion for limiting an angle of the first body to be 15 degrees to 345 degrees relative to the second body.

The present disclosure further provides another assembly method of an assembly structure including a first body, a second body and an assembly portion. The first body has a block portion, and the block portion is for blocking the assembly portion to limit a position of the first body, or to limit the first body to be located at a position at 90 degrees or close to 90 degrees relative to the second body, or to limit the first body to be located a position at 15 degrees to 150 degrees relative to the second body, or to limit an angle of the first body relative to the second body.

### BRIEF DESCRIPTION OF THE DRAWINGS

To more clearly describe the technical solutions of the embodiments of the present disclosure and the prior art, accompanying drawings that need to be used as required in the embodiments are to be briefly introduced. It is obvious that the accompanying drawings below are merely some embodiments of the present disclosure, and other accompanying drawings can be obtained on the basis of the these accompanying drawings by a person of ordinary skill in the art without involving any inventive skill.

FIG. 1 is an appearance schematic diagram of a first specific embodiment of the present disclosure.

FIG. 2 is an exploded schematic diagram of the first specific embodiment of the present disclosure.

FIG. 3 is a schematic diagram of a state of manufacturing of a second specific embodiment of the present disclosure.

FIG. 4 is a schematic diagram of a state of manufacturing of a third specific embodiment of the present disclosure.

FIG. 5 is a schematic diagram of a state of manufacturing of a fourth specific embodiment of the present disclosure.

FIG. 6 is a schematic diagram of a state of manufacturing of a fifth specific embodiment of the present disclosure.

FIG. 7 is a schematic diagram of a state of manufacturing of a sixth specific embodiment of the present disclosure.

FIG. 8 is a schematic diagram of a state of manufacturing of a seventh specific embodiment of the present disclosure.

FIG. 9 is a schematic diagram of a state of manufacturing of an eighth specific embodiment of the present disclosure.

FIG. 10 is a schematic diagram of a state of manufacturing of a ninth specific embodiment of the present disclosure.

FIG. 11 is a schematic diagram of a state of manufacturing of a tenth specific embodiment of the present disclosure.

FIG. 12 is a schematic diagram of a state of manufacturing of an eleventh specific embodiment of the present disclosure.

FIG. 13 is a schematic diagram of a state of use of a twelfth specific embodiment of the present disclosure.

FIG. 14 is a schematic diagram of a state of use of a thirteenth specific embodiment of the present disclosure.

FIG. 15 is a schematic diagram of a state of use of a fourteenth specific embodiment of the present disclosure.

FIG. 16 is a first schematic diagram of a state of use of a fifteenth specific embodiment of the present disclosure.

FIG. 17 is a second schematic diagram of a state of use of the fifteenth specific embodiment of the present disclosure.

FIG. 18 is a schematic diagram of a state of use of a sixteenth specific embodiment of the present disclosure.

FIG. 19 is a schematic diagram of a state of use of a seventeenth specific embodiment of the present disclosure.

FIG. 20 is a schematic diagram of a state of use of an eighteenth specific embodiment of the present disclosure.

FIG. 21 is a schematic diagram of a state of use of a nineteenth specific embodiment of the present disclosure.

FIG. 22 is a schematic diagram of a state of use of a twentieth specific embodiment of the present disclosure.

FIG. 23 is a schematic diagram of a state of use of a twenty-first specific embodiment of the present disclosure.

FIG. 24 is a schematic diagram of a state of use of a twenty-second specific embodiment of the present disclosure.

FIG. 25 is a schematic diagram of a state of use of a twenty-third specific embodiment of the present disclosure.

FIG. 26 is a schematic diagram of a state of use of a twenty-fourth specific embodiment of the present disclosure.

FIG. 27 is a schematic diagram of a state of use of a twenty-fifth specific embodiment of the present disclosure.

FIG. 28 is a schematic diagram of a state of use of a twenty-sixth specific embodiment of the present disclosure.

FIG. 29 is a schematic diagram of a state of use of a twenty-seventh specific embodiment of the present disclosure.

FIG. 30 is a schematic diagram of a state of use of a twenty-eighth specific embodiment of the present disclosure.

FIG. 31 is a schematic diagram of a state of use of a twenty-ninth specific embodiment of the present disclosure.

FIG. 32 is a schematic diagram of a state of use of a thirtieth specific embodiment of the present disclosure.

FIG. 33 is a schematic diagram of a state of use of the thirtieth specific embodiment of the present disclosure.

FIG. 34 is a schematic diagram of a state of use of a thirty-first specific embodiment of the present disclosure.

FIG. 35 is a schematic diagram of a state of use of a thirty-second specific embodiment of the present disclosure.

FIG. 36 is a schematic diagram of a state of use of a thirty-third specific embodiment of the present disclosure.

FIG. 37 is a schematic diagram of a state of use of a thirty-fourth specific embodiment of the present disclosure.

FIG. 38 is a second schematic diagram of a state of use of a thirty-fifth specific embodiment of the present disclosure.

FIG. 39 is a schematic diagram of a state of use of a thirty-sixth specific embodiment of the present disclosure.

FIG. 40 is a schematic diagram of a state of use of a thirty-seventh specific embodiment of the present disclosure.

FIG. 41 is a schematic diagram of a state of use of a thirty-eighth specific embodiment of the present disclosure.

FIG. 42 is a schematic diagram of a state of use of the thirty-eighth specific embodiment of the present disclosure.

FIG. 43 is a schematic diagram of a state of use of a thirty-ninth specific embodiment of the present disclosure.

FIG. 44 is a schematic diagram of a state of use of a fortieth specific embodiment of the present disclosure.

FIG. 45 is a schematic diagram of a state of use of a forty-first specific embodiment of the present disclosure.

FIG. 46 is a schematic diagram of a state of use of a forty-second specific embodiment of the present disclosure.

FIG. 47 is a schematic diagram of a state of use of a forty-third specific embodiment of the present disclosure.

FIG. 48 is a schematic diagram of a state of use of a forty-fourth specific embodiment of the present disclosure.

FIG. 49 is a second schematic diagram of a state of use of a forty-fifth specific embodiment of the present disclosure.

### DETAILED DESCRIPTION OF THE INVENTION

A fluid device according to the embodiments of the present disclosure is further described with the accompanying drawings below.

The above and other technical details, features and effects of the disclosure are to become more readily apparent with the detailed description of the preferred embodiments given with reference to the drawings below. It should be noted that, the directional terms used in the embodiments below, for example, upper, lower, left, right, front and back are given merely with reference to the directions of the accompanying drawings. Thus, the directional terms are for illustration purposes and are not to be construed as limitations to the present disclosure. Moreover, in the embodiments below, the same or similar elements are represented by the same or similar denotations or numerals.

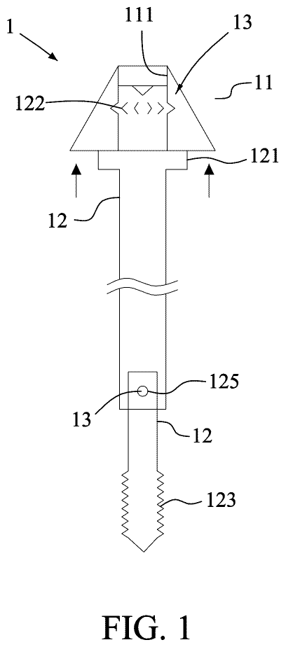

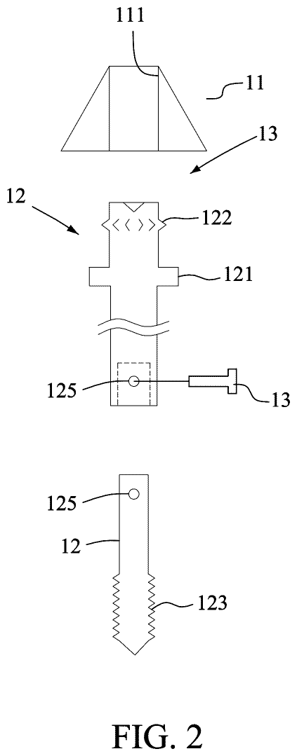

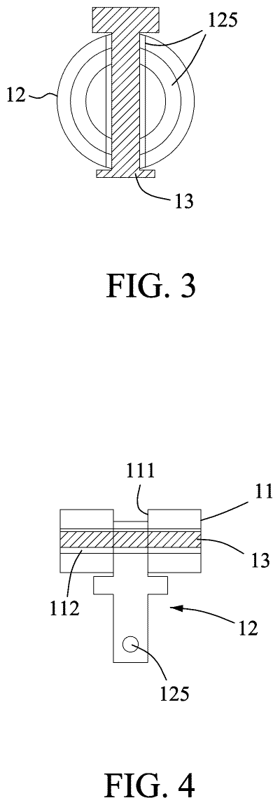

Referring to FIG. 1 to FIG. 3, as shown in the drawings, the present disclosure provides an assembly structure 1 at least including a first body 11, a second body 12 and an assembly portion 13. The assembly portion 13 combines the first body 11 and the second body 12.

In addition to the embodiments above, in one embodiment of the present disclosure, the second body 12 is provided with a stop portion 121, the second body 12 passes through the first body 12, and the stop portion 121 stops at a bottom of the first body 11.

In addition to the embodiments above, in one embodiment of the present disclosure, the assembly portion 13 includes an insert portion 111 and a press portion 112. The insert portion 111 is disposed at the first body 11, the second body 12 passes through the insert portion 111, the press portion 122 is disposed at an outer edge of one end of the second body 12, an engaging portion 123 is provided on the other end of the second body 12 (or the second body 12), and the second body 12 passes through the insert portion 111 and is pressed at an inner edge of the insert portion 111 by the press portion 122. Thus, the first body 11 and the second body 12 can be securely combined.

To put to use, a force can be applied to the first body 11 such that the body 11 drives the engaging portion 123 of the second body 12 to be engagingly connected at a required object. For removal, a force is applied in a reverse direction on the first body 11 such that the first body 11 drives the engaging portion 123 of the second body 12 to be separated from the required object, hence achieving effects of quick coupling and easy removal.

In addition to the embodiments above, in one embodiment of the present disclosure, a plurality of second bodies 12 are provided, and the second bodies 12 are individually combined with each other at least by connecting portions 125, and the connecting portions 125 are individually fixed with each other by the assembly portion 13. Thus, the plurality of second bodies 12 are assembled to form the second body 12.

On the basis of the embodiments above, in an assembly of an assembly structure of the present disclosure, the second body 12 (that is, the second body 12 having the stop portion 121 and the press portion 122) not yet assembled into the second body 12 is passed through the insert portion 111, for the press portion 122 to be pressed at an inner edge of the insert portion 11, the second body 12 is passed through the insert portion 111 for the press portion 122 to be pressed at the inner edge of the insert portion 111, the stop portion 121 is caused to be stopped at a bottom of the first body 11, and the second bodies 12 are combined with each other by the connecting portion 125 in coordination with the assembly portion 13 to form the second body 12.

In addition to the embodiments above, in the assembly method of an assembly structure of the present disclosure, the second bodies 12 can first be combined by the connecting portion 125 in coordination with the assembly portion 13 to form the second body 12, the second body 12 is passed through the insert portion 111 for the press portion 122 to be pressed at an inner edge of the insert portion 111, the second body 12 is passed through the insert portion 111 for the pressed portion 122 to be pressed at the inner edge of the insert portion 111, and the stop portion 121 is caused to be stopped at a bottom of the first body 11.

In addition to the embodiments above, in one embodiment of the present disclosure, each connecting portion 125 can be cylindrical or a through hole, and each assembly portion 13 can be a bolt. Thus, when the second bodies 12 are combined to form the second body 12, actual application requirements can be better met.

In addition to the embodiments above, in one embodiment of the present disclosure, each of the first body 11, the second body 12 and the assembly portion 13 can be an engaging body, a metal structured body, a rivet, a welding body, an expansion connection body or a lock, and is formed of a non-thermal treated metal material or a thermal treated metal material.

Referring to FIG. 4, as shown in the drawing, in addition to the embodiments above, in one embodiment of the present disclosure, the first body 11 is provided with a setup portion 112, one second body 1 of the second bodies 12 is provided with an installation portion 122, the second body 12 passes through the insert portion 111 for the installation portion 122 to correspond with the setup portion 112, the assembly portion 13 passes through the installation portion 122 and the setup portion 112, and the assembly portion 13 can be a bolt or an elastic body so as to combine the first body 11 and the second body 12 with each other. Thus, the first body 11 and the second body 12 can be securely combined.

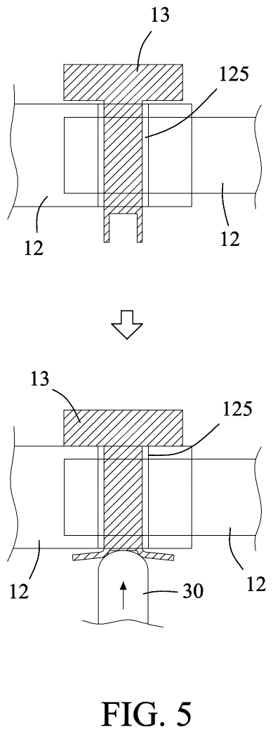

Referring to FIG. 5, as shown in the drawing, in addition to the embodiments above, in one embodiment of the present disclosure, each assembly portion 13 passes through the connecting portions 125 of two second bodies 12, and expansion connection and combination is performed by pressing each assembly portion 13 by a mold 30. Thus, the second bodies 12 can be securely combined to form the second body 12.

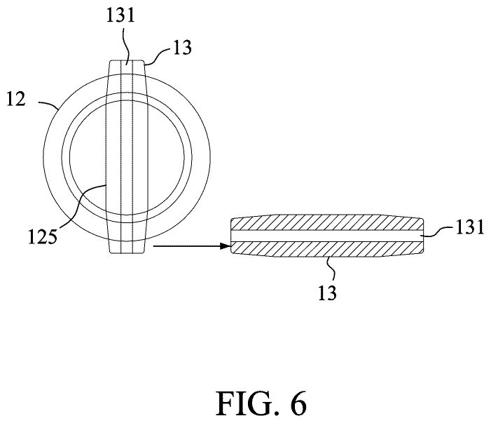

Referring to FIG. 6, as shown in the drawing, in addition to the embodiments above, in one embodiment of the present disclosure, each assembly portion 13 is an elastic body and is squeezed into the connecting portions 125 of two second bodies 12 for elastic bolting, wherein each assembly portion 13 has an elastic squeeze space 131 for each assembly portion 13 to appear as a withdrawn condition when squeezed into the connecting portions 125 of the two second bodies 12. Thus, the second bodies 12 can be securely combined to form the second body 12.

In addition to the embodiments above, in one embodiment of the present disclosure, the assembly portion 13 is an elastic body and is squeezed into the first body 11 so as to be elastically assembled with the second body 12.

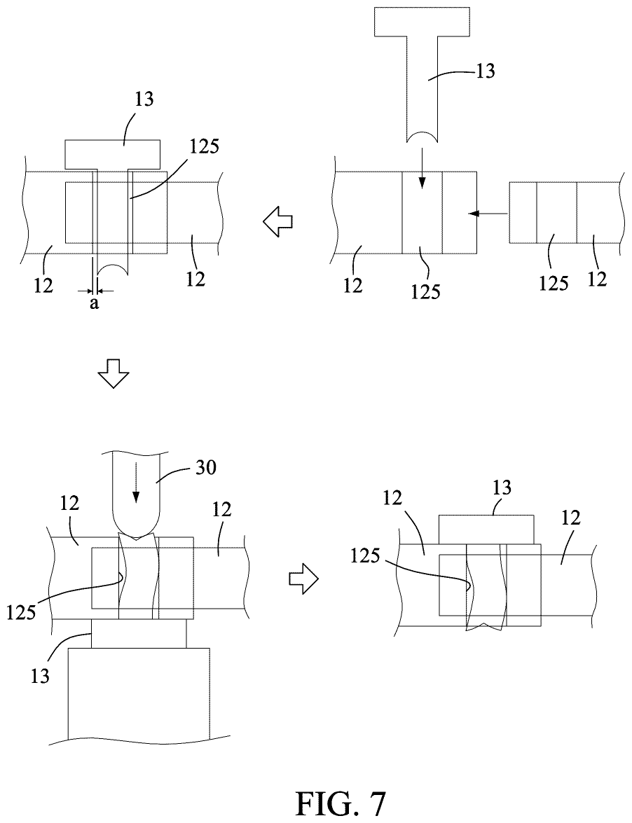

Referring to FIG. 7 to FIG. 9, in addition to the embodiments above, in one embodiment of the present disclosure, a distance between each assembly portion 13 and each connecting portion 125 contains a floating amount a, the floating amount is 0.00001 mm to 5 mm, and each assembly portion 13 is pressed and deformed by the mold 30, for each assembly portion 13 to press or abut against each connecting portion 125 for each floating amount a to be filled, reduced or reset to zero. Thus, multiple second bodies 12 can be assembled in the coordination with the assembly portions 13 and the connecting portions 125, enabling the second body 12 to achieve an effect of structural stability.

In addition to the embodiments above, in one embodiment of the present disclosure, the assembly portions 13 and the connecting portions 125 can be formed of a metal material or a deformable material. Thus, with the material properties of the assembly portions 13 and the connecting portions 125, the floating amount a can be filled, reduced or reset to zero, and multiple second bodies 12 can be assembled with the coordination of the assembly portions 13 and the connecting portions 125 to form the second body 12.

Moreover, the assembly portion 13 can also be formed integrally with the first body 11 or the second body 12.

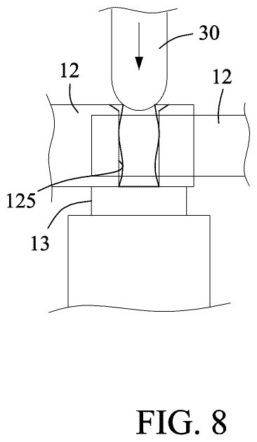

In addition to the embodiments above, in one embodiment of the present disclosure, the assembly portions 13 expand or deform and the floating amounts a are filled, reduce or reset to zero (as shown in FIG. 7), or the assembly portions 13 expand, deform and shorten and the floating amounts are filled, reduced or reset to zero (as shown in FIG. 8). Thus, multiple second bodies 12 can be assembled with the coordination of the assembly portions 13 and the connecting portions 125 to form the second body 12.

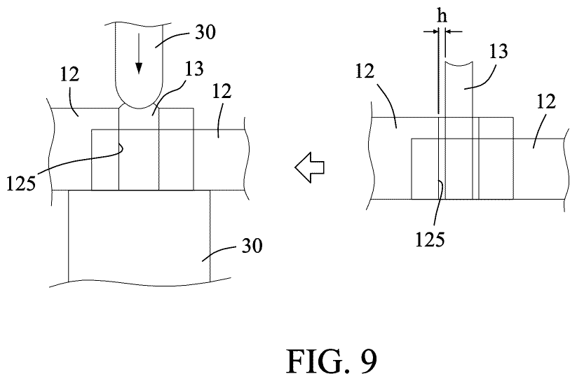

In addition to the embodiments above, in one embodiment of the present disclosure, the assembly portions 13 expand to fill the connecting portions 125, and the floating amounts a are reset to zero (as shown in FIG. 9). Thus, multiple second bodies 12 can be assembled with the coordination of the assembly portions 13 and the connecting portions 125 to form the second body 12.

In addition to the embodiments above, in one embodiment of the present disclosure, the assembly portion 13 is pressed by the mold 30 and is pressed and deformed, for the assembly portion 13 to abut against, press against or support the first body 11 or the second body 12, for the floating amount a between the assembly portion 13 and the first body 11 or the second body 12 to be filled, reduced or reset to zero, or the floating amount a between the first body 11 and the second body 12 to be filled, reduced or reset to zero.

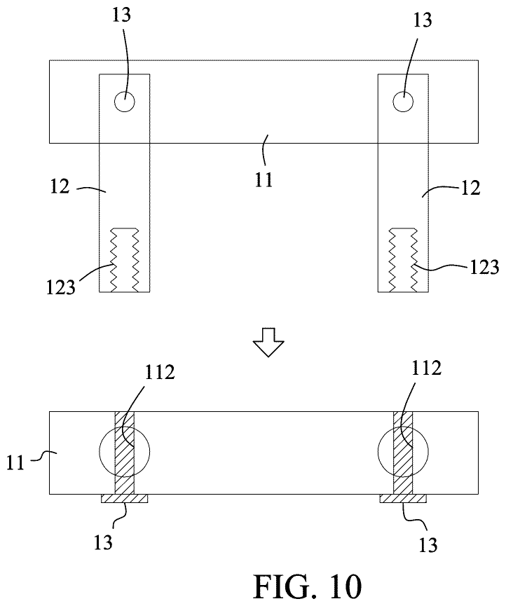

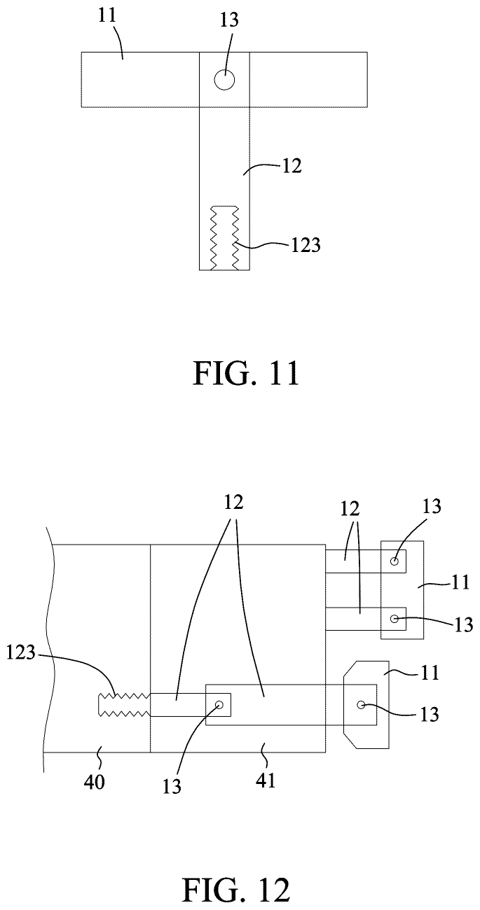

Referring to FIG. 10 to FIG. 12, as shown in the drawings, in addition to the embodiments above, in one embodiment of the present disclosure, the first body 11 and each second body 12 can be combined into a handle (as shown in FIG. 10 and FIG. 11) or a pulling structure, and the assembly structure 1 is applied to an object (as shown in FIG. 12) such as a data center 40, a server 41 (or a storage device or a computer), thereby enabling the present disclosure to better meet actual application requirements.

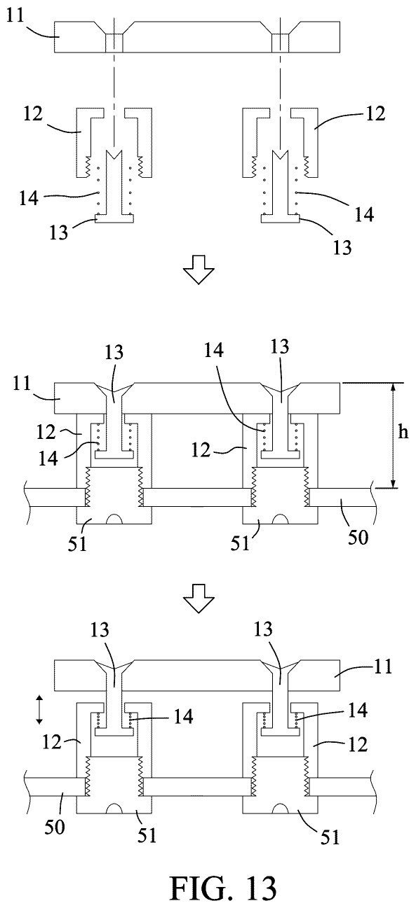

Referring to FIG. 13, as shown in the drawing, in addition to the embodiments above, in one embodiment of the present disclosure, at least two second bodies 12 are further included. Each second body 12 is combined at the first body 11 by one assembly portion 13, and an elastic component 14 is provided between each assembly portion 13 and each second body 12 (or an elastic component 14 is provided between one of the assembly portions 13 and one of the second bodies 12), wherein the first body 11 and each second body 12 can be combined into a handle, a pulling structure or an engaging body, and by applying a force to the first body 11, each elastic component 14 is pulled close to each second body 12 to reduce a height h of each second body 12 (or to reduce a height of the first body 11). Moreover, the second body 12 can also be elastically withdrawn to reduce a height of the assembly structure 1.

In addition to the embodiments above, in one embodiment of the present disclosure, each second body 12 is combined at an object 50 (or formed integrally with an object 50) by locking, riveting, engagement connection, expansion connection or welding, and is combined at the object 50 by locking using a screw 51 in this embodiment, and the object 50 can be a metal body, a shockproof body, an elastic body, a plastic body, a computer, a track body, a casing, a circuit board, a heat dissipater, a chip, a track, a connector, a fan, a casing, an M.2 card, an E1.S card, an E3.S card, a storage device, a server or a data center, or the object 50 is a heat dissipater, or the object 50 is a printed circuit board (PCB) or a casing for placing a chip or a memory, or the object 50 can be moved or removed during an operation of a chip, thereby enabling the present disclosure to better meet actual application requirements.

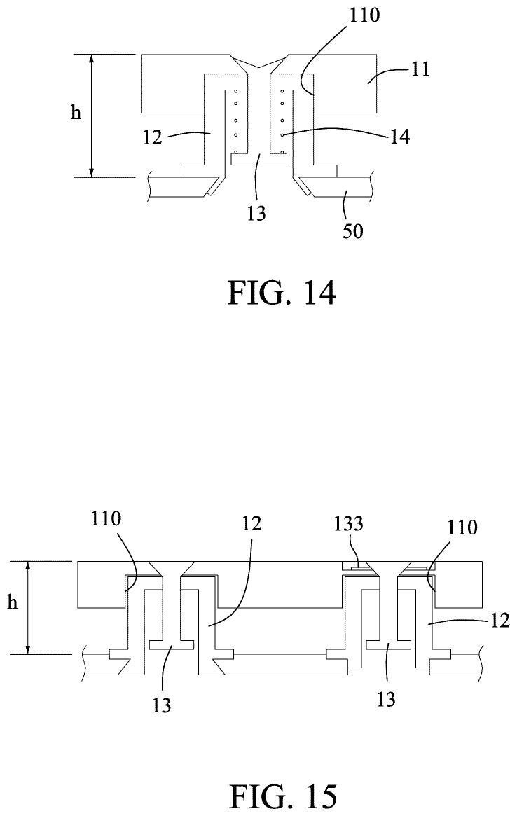

Referring to FIG. 14 and FIG. 15, as shown in the drawings, in addition to the embodiments above, in one embodiment of the present disclosure, the first body 11 is provided with at least two accommodating spaces 110, and the second bodies 12 are respectively disposed in the accommodating spaces 110 to reduce a combination height h of the second bodies 12.

In addition to the embodiments above, in one embodiment of the present disclosure, each accommodating space 110 can be an opening, a step, a recess, a slot, a notch or a through hole, thereby enabling the present disclosure to better meet actual application requirements.

In addition to the embodiments above, in one embodiment of the present disclosure, the first body 11 or the second body 12 can be provided with an accommodating space 110, and the first body 10 or the second body 12 is disposed in the accommodating space 110 to reduce a height of the assembly structure 1.

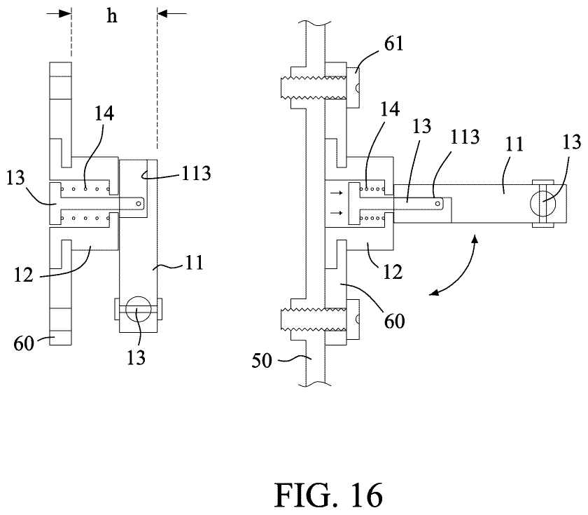

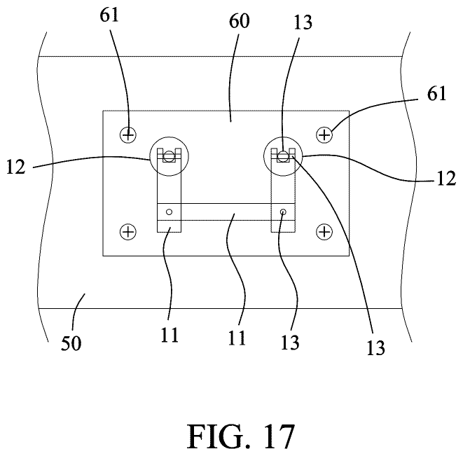

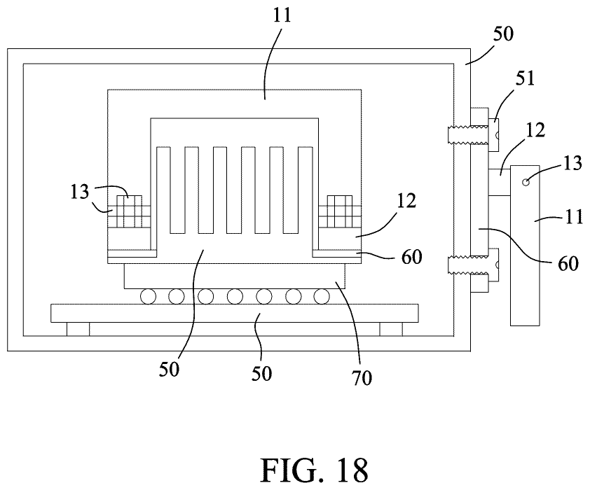

In addition to the embodiments above, in one embodiment of the present disclosure, the assembly portion 13 passes through the second body 12 and enters the first body 11 for expansion connection and assembly. Moreover, the assembly 13 can also pass through the second body 12 and enter the first body 11 for expansion connection and stopping at a stop member 133, thereby enabling the present disclosure to better meet actual application requirements. Referring to FIG. 16 to FIG. 18, as shown in the drawings, in addition to the embodiments above, in one embodiment of the present disclosure, the first body 11 or the second body 12 is disposed at a fixing body 60, the fixing body 60 is assembled at the object 50, and the first body 11 or the second body 12 and the fixing body 50 are riveted, expansion connected, locked, welded, engagingly connected or formed integrally. The assembly of the fixing body 60 and the object 50 is performed by a screw 61 in this embodiment.

In addition to the embodiments above, in one embodiment of the present disclosure, multiple first bodies 11, multiple second bodies 12 and multiple assembly portions 13 are further included. The numbers of the multiple first bodies 11, the multiple second bodies 12 and the multiple assembly portions 13 can be three or more. The first bodies 11 and the second bodies 12 are combined by the assembly portions 13, and an elastic component 14 is provided between each second body 12 and each assembly portion 13. Two ends of each elastic component 14 respectively abut against each assembly portion 13 and each second body 14 to elastically reduce the height h of each second body 12 by each elastic component 14. Moreover, each first body 11 (or each second body 12) can be rotated as needed to reduce the height h of each second body 12 (or each first body 11), thereby enabling the present disclosure to better meet actual application requirements.

In this embodiment, each first body 11 can be rotated, and each assembly portion 13 is blocked by a block portion 113 of each body 11 to limit a position of each first body 11 that is rotated, for each first body 11 to be located at a position at 90 degrees or close to 90 degrees relative to the fixing body 60 and for each elastic component 14 to elastically reduce the height of each second body 12.

In addition to the embodiments above, in one embodiment of the present disclosure, the fixing body 60 can be combined at the object 50 by locking, riveting, engagement connection, expansion connection or welding, and the object 50 can be a metal body, a shockproof body, an elastic body, a plastic body, a computer, a track body, a casing, a circuit board, a heat dissipater, a chip, a track, a connector, a fan, a casing, an M.2 card, an E1.S card, an E3.S card, a storage device, a server or a data center. Moreover, the object 50 can also be a heat dissipater or a PCB or a casing for placing a chip or a memory, or the object 50 can be moved or removed during an operation of a chip, the object 50 is disposed at a heat generator 70 to perform heat dissipation, and the heat generator 70 is a chip or a memory, thereby enabling the present disclosure to better meet actual application requirements.

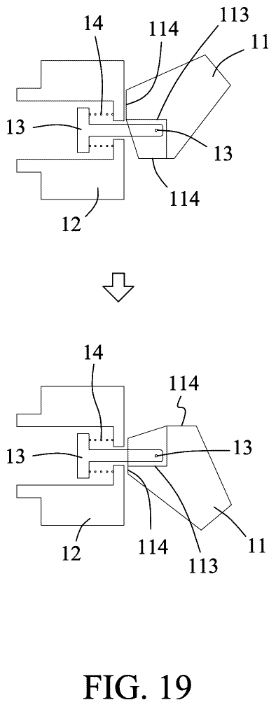

Referring to FIG. 19, as shown in the drawing, in addition to the embodiments above, in one embodiment of the present disclosure, the elastic component 14 is provided between the second body 12 and the assembly portion 13, and two ends of the elastic component 14 respectively abut against the assembly portion 13 and the first body 11 to elastically reduce the height of the first body 11, or for the first body 11 to rotate to reduce the height of the first body 11, or the first body 11 has a block portion 113, which is two in number in this embodiment.

On the basis of the embodiments above, the first body 11 can be rotated to press against the second body 12 by one of the block portions 113 to have the one to block the assembly portion 13 to limit a position of the first body 11 or a position of the first body 11 that is rotated, to limit the first body 11 at a position located at 90 degrees or close to 90 degrees relative to the second body 12, or to press against the second body 12 by the other block portion 113 to have the other to limit a position of the first body 12 that is rotated, to limit the first body 11 at a position located at 15 degrees to 150 degrees relative to the second body 12, or to limit an angle of the first body 11 relative to the second body 12, thereby enabling the present disclosure to better meet actual application requirements.

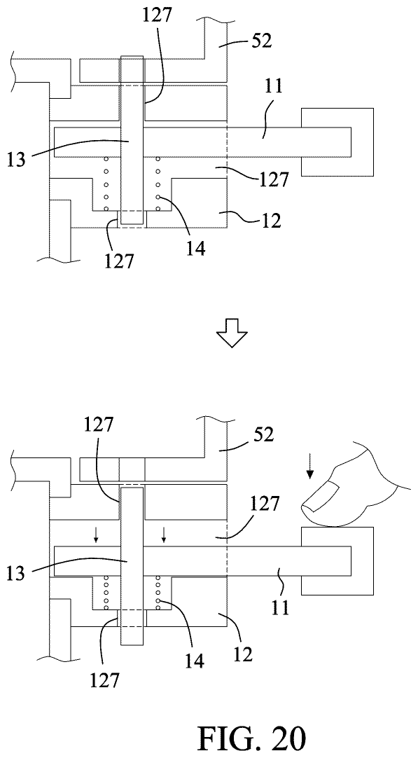

Referring to FIG. 20, as shown in the drawing, in addition to the embodiments above, in one embodiment of the present disclosure, the first body 11 and the assembly portion 13 can be combined into a module and be disposed at the second body 12, and two ends of an elastic component 14 respectively abut against the first body 11 and the second body 12 for the assembly portion 13 to pass through an opening 127 of the second body 12 and to be engaged into another object 52, thereby enabling the present disclosure to better meet actual application requirements.

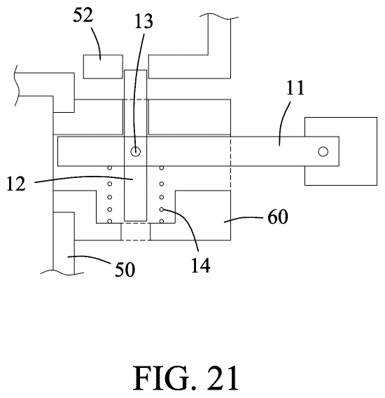

Referring to FIG. 21, as shown in the drawing, in addition to the embodiments above, in one embodiment of the present disclosure, the first body 11 and the second body 12 are combined into a module and are disposed at the fixing body 60, and two ends of an elastic component 14 respectively abut against the first body 11 and the fixing body 60 for the second body 12 to be engaged into another object.

In addition to the embodiments above, in one embodiment of the present disclosure, the numbers of the first body 11, the second body 12 and the assembly portion 13 are respectively one, two or three, for the first body 11, the second body 12 and the assembly portion 13 to be formed integrally or to be combined into a module, thereby enabling the present disclosure to better meet actual application requirements.

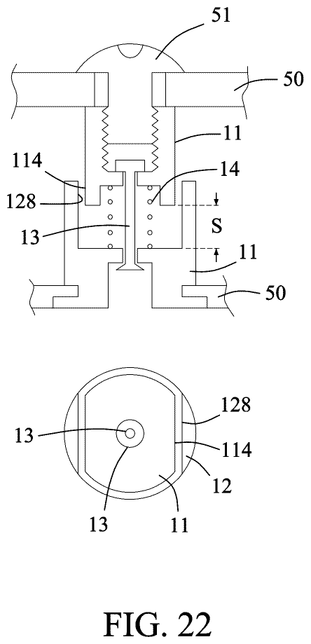

Referring to FIG. 22 to FIG. 28, as shown in the drawings, in addition to the embodiments above, in one embodiment of the present disclosure, the assembly portion 13 is vertically assembled or horizontally assembled at the first body 11 or the second body 12, and the first body 11, the second body 12 and the assembly portion 13 have the elastic component 14 (or a shockproof component) in between to define an elastic space s (a shockproof space, a height adjustment space or a height abutment space), thereby enabling the present disclosure to better meet actual application requirements.

In addition to the embodiments above, in one embodiment of the present disclosure, the first body 11 and the second body 12 are respectively assembled at two objects to provide an elastic space (a shockproof space, a height adjustment space or a height abutment space) between the objects, so as to be used as buffering or position adjustment (height adjustment or height abutment) between the objects. For example, when the first body 11 and the second body 12 are assembled at two objects 50, if the two objects 50 are not level or not level enough in between or are warped, the first body 11 and the second body 12 can provide a buffering space via the elastic space s, so as to better perform coupling, assembling, engaging connection, position regulation or position adjustment, thereby enabling the present disclosure to better meet actual application requirements.

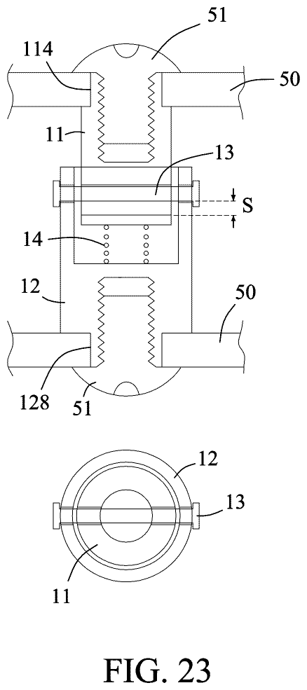

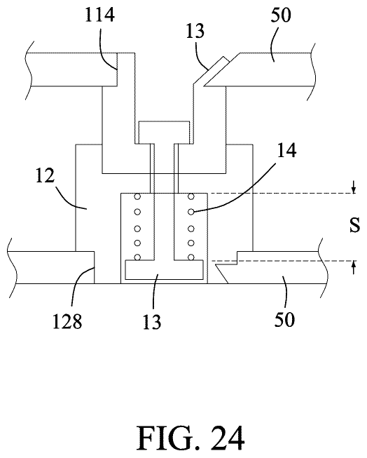

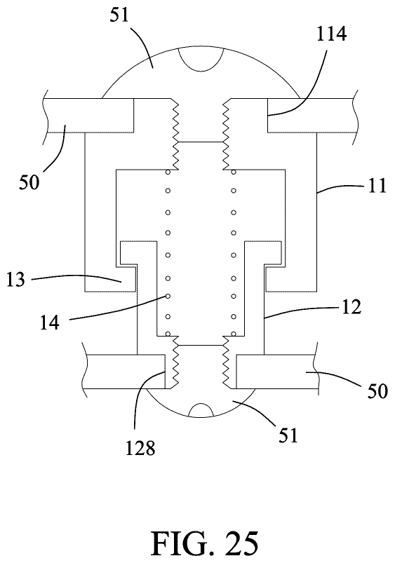

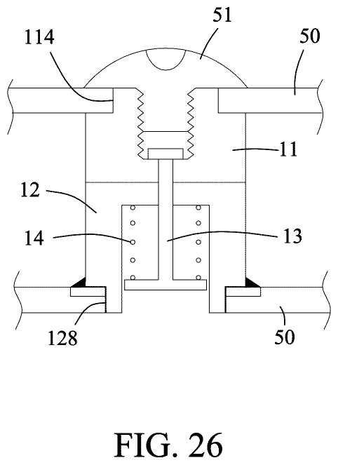

In addition to the embodiments above, in one embodiment of the present disclosure, the assembly portion 13 is vertically assembled (as shown in FIG. 22, FIG. 24 and FIG. 26) or horizontally assembled (as shown in FIG. 23 and FIG. 25) at the first body 11 and the second body 12, and the elastic component 14 causes the first body 11 and the second body 12 to be located at an interval position, a pulled-close position, a height adjustment position or a height abutment position.

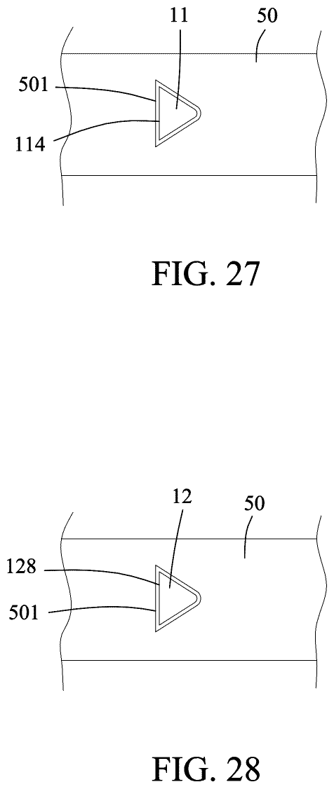

In addition to the embodiments above, in one embodiment of the present disclosure, the first body 11 and the second body 12 can be provided with anti-rotation portions 114 and 128, respectively. The anti-rotation portions 114 and 128 are respectively for preventing mutual rotation relative to a corresponding anti-rotation portion 501 of the object 50 (as shown in FIG. 27 and FIG. 28), or the anti-rotation portions 114 and 128 are preventing rotation when locked at the object 50, or the anti-rotation portions 114 and 128 are for preventing rotation when locked at the object 50 to further prevent the first body 11 and the second body 12 from a reduced or loosened screw locking force caused by locking torque, or the first body 11 and the second body 12 are respectively provided with a pair of anti-rotation portions 114 and 128 for preventing rotation, thereby enabling the present disclosure to better meet actual application requirements.

In addition to the embodiments above, in one embodiment of the present disclosure, the first body 11 or the second body 12 is locked (as shown in FIG. 22, FIG. 23, FIG. 25 and FIG. 26), riveted (as shown in FIG. 22 and FIG. 24), expansion connected (as shown in FIG. 24), welded (as shown in FIG. 26), adhered or engagingly connected at one object 50 or two objects 50, thereby enabling the present disclosure to better meet actual application requirements.

In addition to the embodiments above, in one embodiment of the present disclosure, the assembly portion 13 is an extension structure of the first body 11, and is for mutually interfering, engaging or assembling with an extension structure of the second body 12, or the assembly portion 13 is an extension structure integrally formed with the first body 11 and is for mutually interfering, engaging or assembling with the extension structure of the second body 12, thereby enabling the present disclosure to better meet actual application requirements.

In addition to the embodiments above, in one embodiment of the present disclosure, the assembly portion 13 is an extension structure of the second body 12 and is for mutually interfering, engaging or assembling with an extension structure of the first body 11, and the assembly portion 13 is an extension structure integrally formed with the second body 12 and is for mutually interfering, engaging or assembling with the extension structure of the first body 11, thereby enabling the present disclosure to better meet actual application requirements.

In addition to the embodiments above, in one embodiment of the present disclosure, the first body 11 and the second body 12 can be concurrently or separately assembled a same object 50 or different objects 50, the object 50 can be a metal plate, a circuit board or a plastic plate. For example, the first body 11 is assembled at a metal plate and the second body 12 is assembled at a circuit board, or the first body 11 is assembled at a circuit board and the second body 12 is assembled at another circuit board, or the first body 11 is assembled at a circuit board and the second body 12 is assembled at a plastic plate, or the first body 11 is assembled at a metal plate and the second body 12 is assembled at a plastic plate, or the first body 11 is assembled at a plastic plate and the second body 12 is assembled at another plastic plate, or the first body 11 is assembled at a metal plate and the second body 12 is assembled at another metal plate, thereby enabling the present disclosure to better meet actual application requirements.

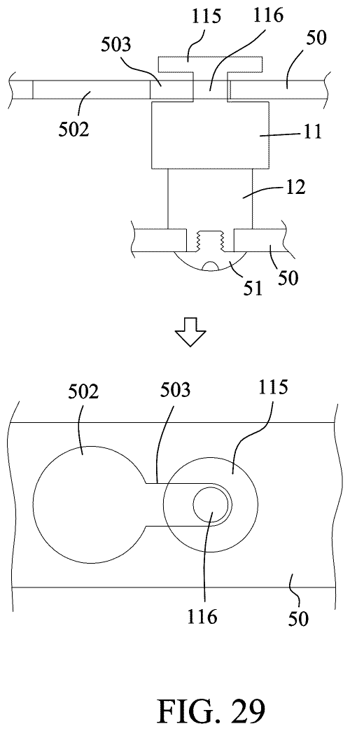

Referring to FIG. 29, as shown in the drawing, in addition to the embodiments above, in one embodiment of the present disclosure, the first body 11 has a head 115 and a neck 116 for being engagingly connected at the object 50, and the head 115 passes through an entry portion 502 of the object 50 and is engagingly connected at an engagement receiving portion 503 of the object 50 by the neck 116, so as to complete quick coupling and separation of at least two objects to achieve effects of repeated quick coupling and separation.

Moreover, the first body 11 has a head 115 and a neck 116 for being engagingly connected at the object 50, and the elastic component 14 (or the shockproof component) is provided between the first body 11 and the second body 12, and the elastic component 14 is for defining the elastic space s (or the shockproof space), thereby enabling the present disclosure to better meet actual application requirements.

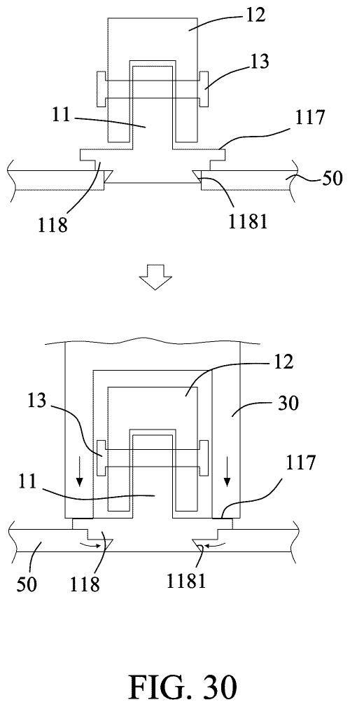

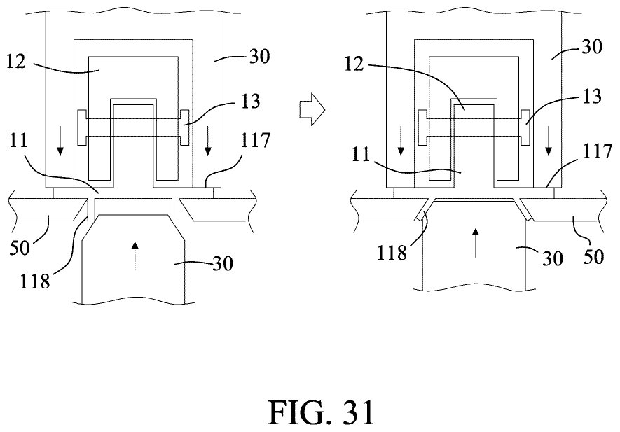

Referring to FIG. 30 and FIG. 31, as shown in the drawings, in addition to the embodiments above, in one embodiment of the present disclosure, the first body 11 has a shoulder 117. The shoulder 117 is for blocking or pressing against the mold 30 for a material of the object 50 to flow into or enter a material entry portion 1181 of a combining portion 118 of the first body 11, so as to securely combine the first body 11 with the object 50 (as shown in FIG. 30).

In addition to the embodiments above, in one embodiment of the present disclosure, the shoulder 117 is for blocking or pressing against the mold 30 for a material of the object 50 to be fittingly connected at the combining portion 118 of the first body 11 and securely expansion connecting the first body 11 at the object 50, so as to securely combine the first body 11 with the object 50 (as shown in FIG. 31).

In addition to the embodiments above, in one embodiment of the present disclosure, the first body 11, the second body 12 or the object 50 can be formed of a metal material, or the first body 11 is formed of a thermal treated metal material or plastic material, or a hardness of the first body 11 is greater than that of the object 50, further allowing a material of the object 50 to enter or flow into the material entry portion 1181 of the first body 11 when the first body 11 is riveted and pressed at the object 50.

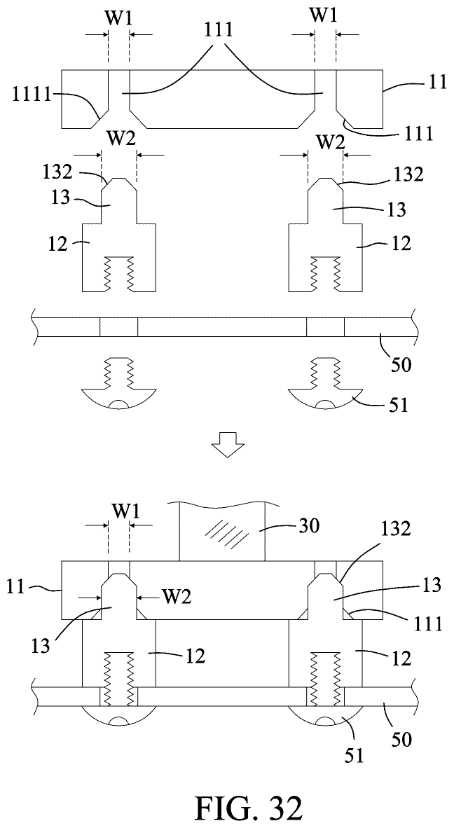

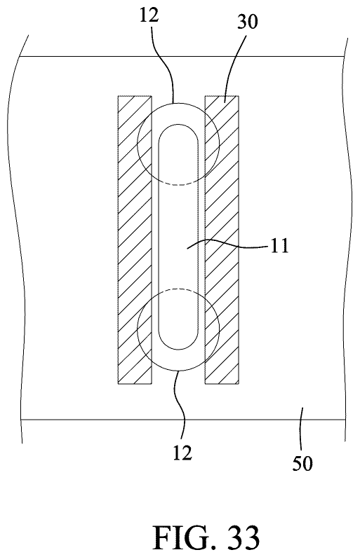

Referring to FIG. 32 and FIG. 33, as shown in the drawings, in addition to the embodiments above, in one embodiment of the present disclosure, the assembly portion 13 is riveted or pressed at the first body 11 and the second body 12 for the first body 11 and the second body 12 to be assembled with each other, wherein a width w1 of the assembly portion 13 is greater than a width w2 of the insert portion 111 of the first body 11 so as to interfere with, squeeze or abut against a material for assembly.

In addition to the embodiments above, in one embodiment of the present disclosure, the insert portion 111 has a guide portion 1111. The guide portion 1111 guides the assembly portion 13 for assembly, or the guide portion 1111 guides a corresponding guide portion 132 of the assembly portion 13 for assembly, thereby enabling the present disclosure to better meet actual application requirements.

In addition to the embodiments above, in one embodiment of the present disclosure, a width of the assembly portion 13 is 0.000001 mm to 5 mm, for the assembly portion 13 to interfere with, squeeze or abut against the material of the insert portion 111 for assembly.

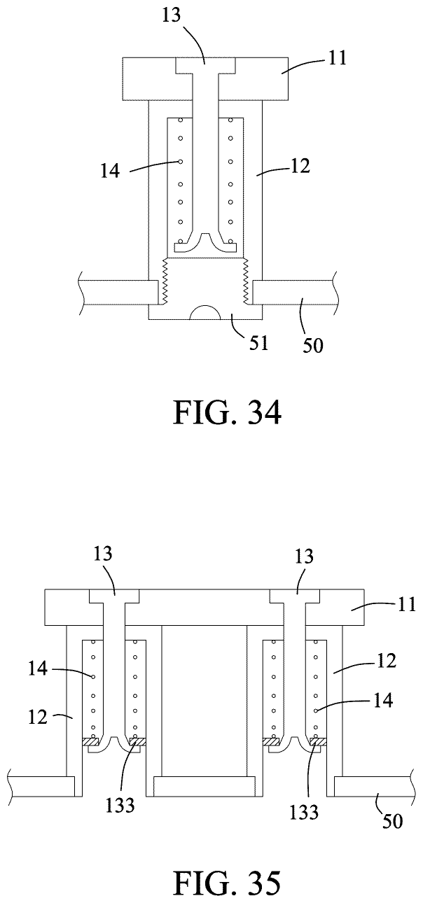

Referring to FIG. 34, as shown in the drawing, in addition to the embodiments above, in one embodiment of the present disclosure, the assembly portion 13 passes through the first body 11 and enters the second body 12 for expansion connection and assembly, wherein two ends of an elastic component 14 respectively abut against the second body 12 and the assembly portion 11, further for the first body 11 and the second body 12 to coordinate with the assembly portion 13 and be combined into a handle, thereby enabling the present disclosure to better meet actual application requirements.

Referring to FIG. 35, as shown in the drawing, in addition to the embodiments above, in one embodiment of the present disclosure, the assembly portion 13 passes through the first body 11 and enters the second body 12 for expansion connection and stopping at the stop member 133, wherein two ends of an elastic component 14 respectively abut against the second body 12 and the stop member 133, further for the first body 11 and the second body 12 to coordinate with the assembly portion 13 and be combined into a handle, thereby enabling the present disclosure to better meet actual application requirements.

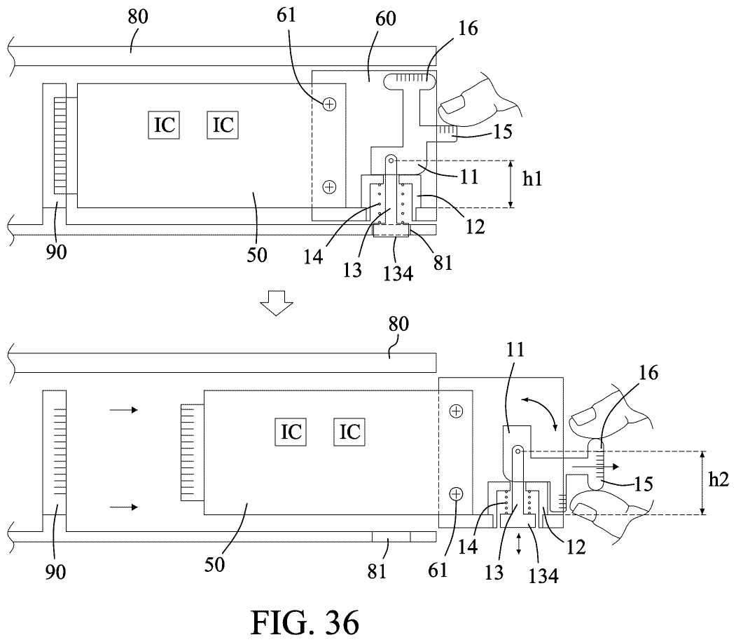

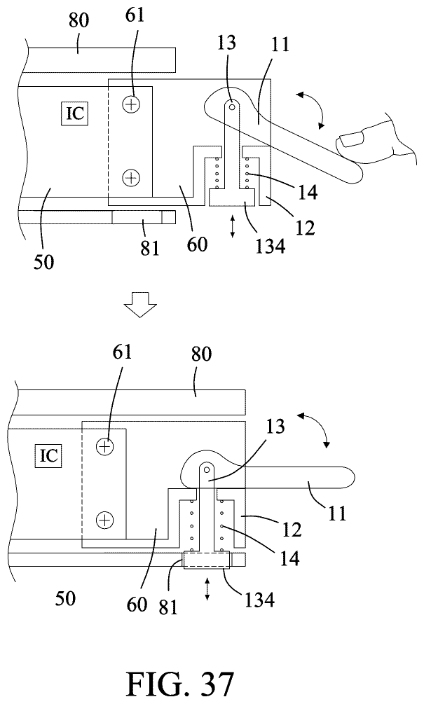

Referring to FIG. 36 and FIG. 37, as shown in the drawings, in addition to the embodiments above, in one embodiment of the present disclosure, the assembly portion 13 has an engaging portion 134 which is for being engagingly connected at the object 50.

In addition to the embodiments above, in one embodiment of the present disclosure, the engaging portion 134 is for being driven by movement or rotation of the first body 11, for the engaging portion 134 to be engagingly connected at an engaged object 80 or be disengaged from the engaged object 80.

In addition to the embodiments above, in one embodiment of the present disclosure, the engaging portion 134 is for being driven by the first body 11 located different positions at a first height h1 or a second height h2, for the engaging portion 134 to be engagingly connected at the engaged object 80 or be disengaged from the engaged object 80, wherein the second height h2 is greater than the first height h1.

In addition to the embodiments above, in one embodiment of the present disclosure, the engaging portion 134 is for being driven by movement of the first body 11 so as to be engagingly connected at the object 50 or be disengaged from the engaged object 80, wherein the fixing body 60 (or the second body 12) to which the second body 12 is assembled is for being combined at the object 50.

In addition to the embodiments above, in one embodiment of the present disclosure, the engaging portion 134 is disengaged from the engaged object 80 which is a casing, or the first body 11 (or the second body 12) is pulled or operated to remove (by means of hot-plugging) the object 50 which is a memory from a connector 90, or the engaging portion 134 is engagingly connected at the engaged object 80 which is a casing for the object 50 which is a memory to be plugged/unplugged (by means of hot-plugging) into/from the connector 90.

In addition to the embodiments above, in one embodiment of the present disclosure, the first body 11 has a press portion 15 and a pull portion 16, for the press portion 15 to be first pressed and rotated and then the pull portion 16 to be pulled.

On the basis of the embodiments above, to put to use, the engaging portion 134 can be engagingly connected at the object 50, and the engaging portion 134 is driven by the first body 11 so as to be engagingly connected in an engaged hole 81 of the engaged object 80 for the first body 11 to be located at a position of the first height h1. In this embodiment, the object 50 can be a memory, and the engaged object 80 can be a casing. When the engaging portion 134 is engagingly connected at the engaged object 80 by the method above, the object 50 can be simultaneously plugged/unplugged into/from the connector 90 by means of hot-plugging, thereby completing quick coupling of at least two objects.

When disengagement is desired, the press portion 15 is first pressed and rotated, and the pull portion 16 is pulled downward (or rotated) for the first body 11 to be located at a position at the second height h2, and the first body 11 is rotated to drive the engaging portion 134 to move away from the engaged hole 81 of the engaged object 80 for the engaging portion 134 to be disengaged from the engaged object 80. Then, the first body 11 is pulled to hot-plug the object 50 into the connector 90, thereby completing quick separation of at least two objects and achieving effects of repeated quick coupling and separation.

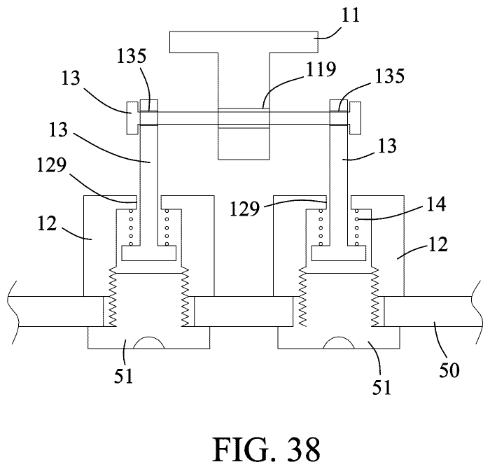

Referring to FIG. 38 to FIG. 42, as shown in the drawings, in addition to the embodiments above, in one embodiment of the present disclosure, at least one first body 11, two second bodies 12 and three assembly portions 13 combined with each other are included. The first body 11, the two second bodies 12 and two of the assembly portions 13 respectively have through holes 119, 129 and 135 for being mutually combined with the assembly portions 13 (as shown in FIG. 38), thereby enabling the present disclosure to better meet actual application requirements.

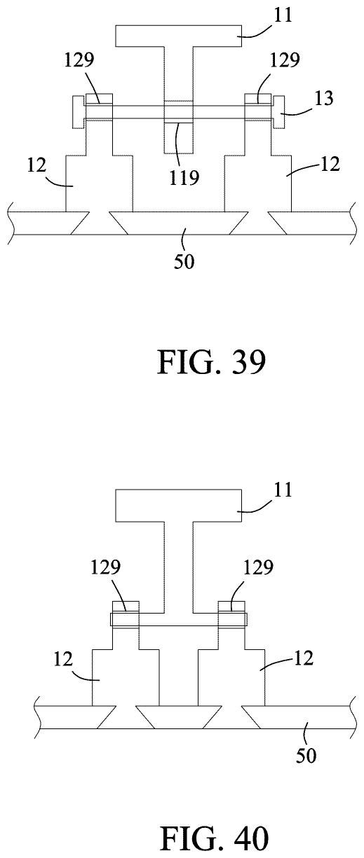

In addition to the embodiments above, in one embodiment of the present disclosure, at least one first body 11, two second bodies 12 and one assembly portions 13 are included. The first body 11 and the two second bodies 12 respectively have through holes 119 and 129 for being mutually combined with the assembly portion 13 (as shown in FIG. 39), thereby enabling the present disclosure to better meet actual application requirements.

In addition to the embodiments above, in one embodiment of the present disclosure, at least one first body 11 and the two second bodies 12 are combined with each other, wherein the two second bodies 12 respectively have through holes 129 for being mutually combined with the first body 11 (as shown in FIG. 40), thereby enabling the present disclosure to better meet actual application requirements.

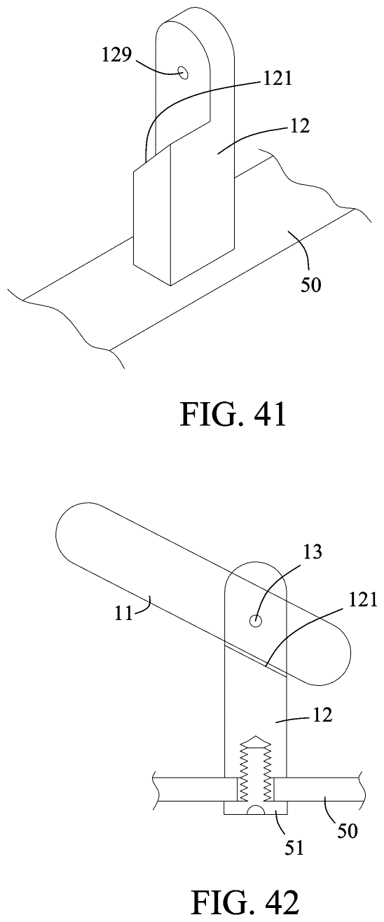

In addition to the embodiments above, in one embodiment of the present disclosure, the second body 12 has a stop portion 121 for limiting a position and an angle of the first body 11 (as shown in FIG. 41 and FIG. 42), thereby enabling the present disclosure to better meet actual application requirements.

In addition to the embodiments above, in one embodiment of the present disclosure, the stop portion 121 is for limiting an angle of the first body 11 to be 15 degrees to 345 degrees relative to the second body 12, thereby enabling the present disclosure to better meet actual application requirements.

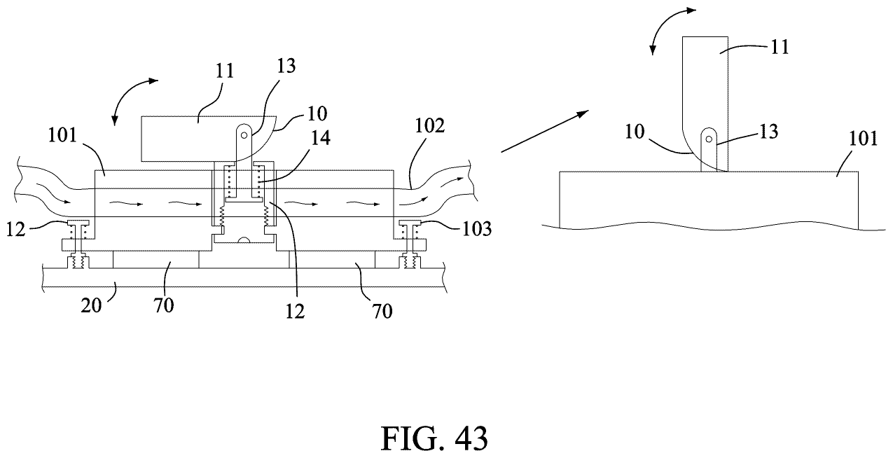

Referring to FIG. 43 to FIG. 46, as shown in the drawings, in addition to the embodiments above, in one embodiment of the present disclosure, the first body has a rotating portion 10 (or a moving portion), or the rotating portion 10 (or the moving portion) can be a structure of a sloped surface, an arc surface, a curved surface or a non-right-angle surface, and abuts against the second body 12 and the assembly portion 13 by an elastic component 14, for the rotating portion 10 (or the moving portion) to be elastically driven to rotate or move so as to reduce a height of the first body 11 (as shown in FIG. 43 to FIG. 45), thereby enabling the present disclosure to better meet actual application requirements.

In addition to the embodiments above, in one embodiment of the present disclosure, the assembly structure 1 is for being assembled at a heat dissipater 101 (or the assembly structure 1 is a heat dissipater), and the heat dissipater 101 is for dissipating heat of the heat generator 70, wherein the heat dissipater 101 has a passage 102 for a cooling fluid to flow through for heat dissipation, the heat dissipater 101 has an engaging body 103 which is for being engagingly connected at the object 50, and the object 50 is provided with the heat dissipater 70, a printed circuit board, a metal body or a non-metal body. Thus, the heat dissipater 101 can be engagingly connected at the object 20 by the engaging body 103, and a heat source of the heat generator 70 can be absorbed by the heat dissipater 101, so as to dissipate heat by using the heat dissipater 101 or dissipate heat by using the heat dissipater 101 in coordination with the passage 102 (as shown in FIG. 43).

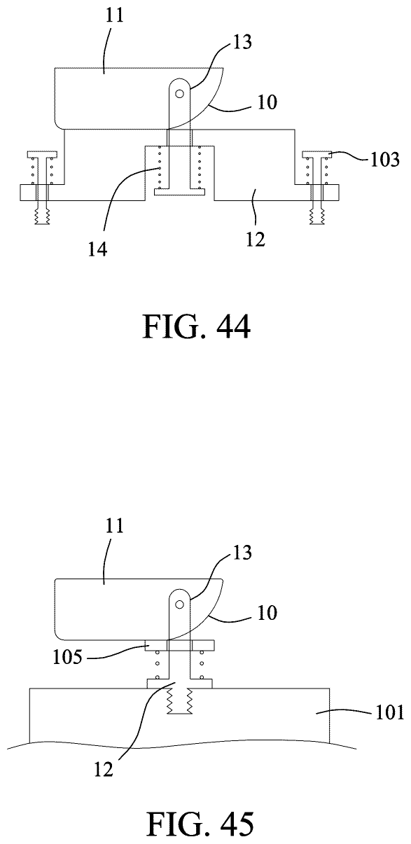

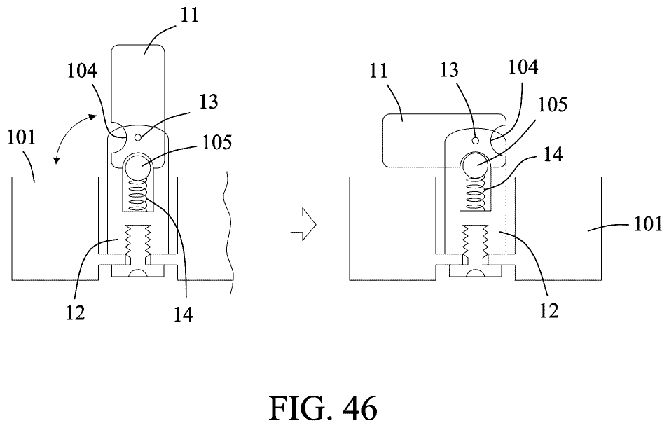

In addition to the embodiments above, in one embodiment of the present disclosure, the second body 12 can be a heat dissipater, or the second body 12 and the heat dissipater 101 are formed integrally (as shown in FIG. 44), or the second body 12 is installed at the heat dissipater 101 (as shown in FIG. 43, FIG. 45 and FIG. 46), thereby enabling the present disclosure to better meet actual application requirements.

In addition to the embodiments above, in one embodiment of the present disclosure, the first body 11 has a limiting portion 104, the limiting portion 104 is for limiting a position of the first body 11 that is rotated, and the second body 12 has an elastic component 14 which for abutting against the limiting portion 104, or the second body 12 has an elastic component 14 which is for abutting against an intermediator 105 at the limiting portion 101 so as to reduce a height of the first body 11 (as shown in FIG. 46), thereby enabling the present disclosure to better meet actual application requirements.

In addition to the embodiments above, in one embodiment of the present disclosure, the second body 12 has an elastic component 14 which is for abutting against the first body 11 to reduce a height of the first body 11, or the second body 12 has an elastic component 14 which is for abutting against the intermediator 105 for the intermediator 105 to abut against the first body so as to reduce a height of the first body 11 (as shown in FIG. 45 and FIG. 46), thereby enabling the present disclosure to better meet actual application requirements.

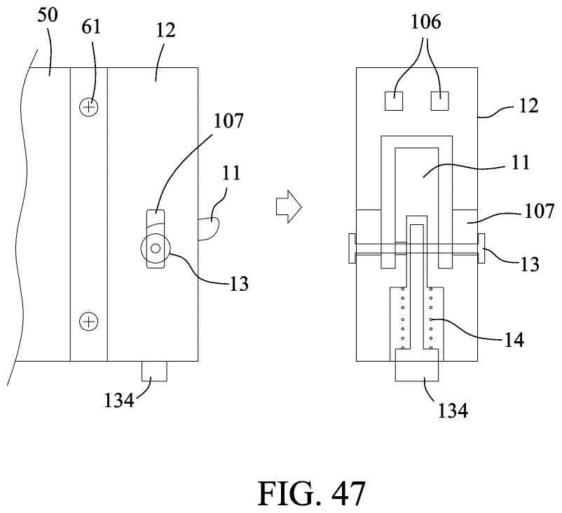

Referring to FIG. 47, as shown in the drawing, in addition to the embodiments above, in one embodiment of the present disclosure, the assembly portion 13 passes through both the second body 12 and the first body 11 for assembly, the second body 12 can be additionally installed with a light emitter 106 (for example, a light emitting diode), the second body 12 has a setup portion 107, and the setup portion 107 can be a movement space for the assembly portion 13 to move at the setup portion 107, thereby enabling the present disclosure to better meet actual application requirements.

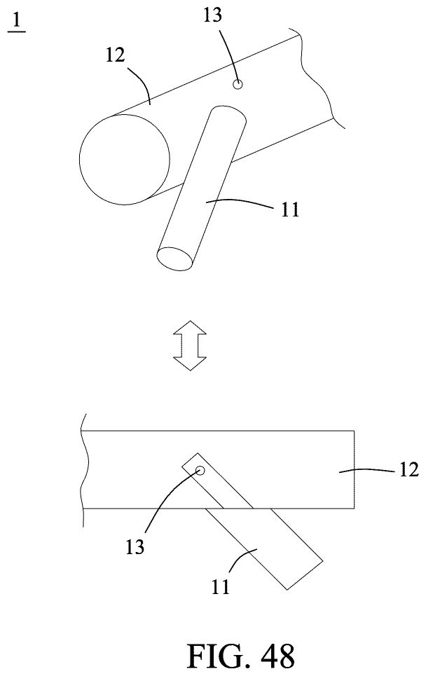

Referring to FIG. 48, as shown in the drawing, in addition to the embodiments above, in one embodiment of the present disclosure, the first body 11 is disposed at an angle at the second body 12, the assembly portion 13 passes through both the second body 12 and the first body 11 for assembly, and an angle between the first body 11 and the second body 12 can be 15 degrees to 345 degrees, thereby enabling the present disclosure to better meet actual application requirements.

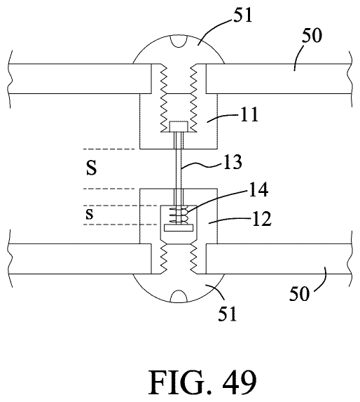

Referring to FIG. 49, as shown in the drawing, in addition to the embodiments above, in one embodiment of the present disclosure, the first body 11 and the second body 12 have an elastic component 14 (or a shockproof element) in between, the elastic component 14 sleeves the assembly portion 13 to define an elastic space s (a shockproof space, a height adjustment space or a height abutment space), the first body 11 and the second body 12 are respectively assembled at objects 50, and a distance between the two objects 50 is greater the first body 11 and the second body 12, wherein the two objects 50 are not horizontal in between, or wherein one of the objects 50 is non-planar or has a non-uniform thickness, or the two objects 50 are non-planar and have non-uniform thicknesses, or a distance between the two objects 50 is less than an accumulated height of the first body 11, the second body 12 and a distance of travel of the elastic component 14 (or the shockproof element), for the first body 11, the second body 12, the assembly portion 13 and the elastic component 14 (or the shockproof element) to perform elastic ascending or elastic descending, or for the two objects 50 to be assembled to provide shockproofness for the two objects 50 or shockproofness for one of the objects 50.

In conclusion, the assembly structure and the assembly method thereof are capable of engagingly connecting an engaged object or disengaging an engaged object, so as to complete quick coupling and separation of at least two objects to achieve effects of repeated quick coupling and separation

It should be noted that the embodiments of the present invention are described above for illustration purposes and are not to be construed as limitations to the scope of the claims of the present invention.

What is claimed is:

1. An assembly structure, being characterized in that, the assembly structure comprises:
a first body;
a second body; and
an assembly portion, combining the first body and the second body.

2. The assembly structure according to claim 1, being characterized in that, the first body is provided with an insert portion, and the second body passes through the insert portion.

3. The assembly structure according to claim 1, being characterized in that, the assembly portion comprises an insert portion and a press portion, the insert portion is disposed at the first body, the press portion is disposed at the second body, and the second body passes through the insert portion or is for being pressed at the insert portion by the press portion.

4. The assembly structure according to claim 1, being characterized in that, the first body is provided with an insert portion and a setup portion, or the second body is provided with an installation portion, or the second body passes through the insert portion and corresponds the installation portion with the setup portion, or the assembly portion passes through the installation portion and is assembled with the setup portion, or is for the first body and the second body to be combined with each other.

5. The assembly structure according to claim 1, being characterized in that, the first body and the second body are combined with each other by connecting portions, or the connecting portions have a floating amount in between, or the assembly portion is pressed and deformed, or the assembly portion abuts against, presses against and supports the connecting portions for the floating amount to be filled, reduced or reset to zero, or the assembly portion and the first body have a floating amount in between, or the assembly portion and the second body have a floating amount in between, or the first body and the second body have a floating amount in between, or the floating is 0.0001 mm to 5 mm, or the assembly portion expands or deforms, or the floating amount is filled, reduced or reset to zero, or the assembly portion expands, deforms or shortens, or the floating amount is filled, reduced or reset to zero.

6. The assembly structure according to claim 1, being characterized in that, the assembly portion is for being pressed by a mold for expansion connection and combination, or wherein the assembly portion is an elastic body, or the assembly portion is for being squeezed in for elastic assembly, or wherein the assembly portion has an elastic squeeze space for the assembly portion to appear as a withdrawn condition when squeezed in, or wherein the assembly portion is for being pressed by a mold, or the assembly portion is pressed and deformed, for the assembly portion to abut against, press against or support the first body or the second body, or for a floating amount between the assembly portion and the first body or the second body to be filled, reduced or reset to zero, or for a floating amount between the first body and the second body to be filled, reduced or reset to zero.

7. The assembly structure according to claim 1, being characterized in that, at least two second bodies are further comprised, each of the second bodies is combined at the first body by an assembly portion, or an elastic component is provided between each of the assembly portions and each of the second bodies, or wherein an elastic component is provided between one of the assembly portions and one of the second bodies, or the first body and each of the second bodies are combined into a handle, a pull structure or an engaging body, the elastic component pulls close the second body, or is for reducing a height of the second body or reducing a height of the first body, or is for the second body to be elastically withdrawn, or is for reducing a height of the assembly structure, or the first body or the second body is provided with an accommodating space, the first body or the second body is accommodated in the accommodating space, or for reducing a height of the assembly structure, or each of the accommodating spaces is an opening, a step, a recess, a slot, a notch or a through hole.

8. The assembly structure according to claim 1, being characterized in that, the first body or the second body is disposed at a fixing body, or the fixing body is assembled at an object, or the first body or the second body and the fixing body are riveted, expansion connected, locked, welded, engagingly connected or formed integrally, or the fixing body is combined at the object by locking, riveting, engaging connection, expansion connection or welding, or the object is a metal body, a plastic body, a computer, a circuit board, a heat dissipater, a chip, a track, a connector, a fan, a casing, an M.2 card, an E1.S card, an E3.S card, a storage device, a server or a data center, or the object is a heat dissipater, or the object is disposed at a heat generator to perform heat dissipation, or the heat generator is a chip or a memory, or the object is a printed circuit board (PCB) or a casing for placing a chip or a memory, or the object is movable or removable during an operation of a chip.

9. The assembly structure according to claim 1, being characterized in that, an elastic component is provided between the second body and the assembly portion, or two ends of the elastic component respectively abut against the assembly portion and the second body so as to reduce a height of the second body by the elastic component, or for the first body or the second body to be rotated so as to reduce a height of the first body or the second body.

10. The assembly structure according to claim 1, being characterized in that, the first body has a block portion, or the block portion is for blocking the assembly portion to limit a position of the first body that is rotated, or to limit the first body to be located at a position at 90 degrees or close to 90 degrees relative to the second body, or to limit the first body to be located at a position at 15 degrees to 150 degrees relative to the second body, or to limit an angle of the first body located at the second body, or the first body has a block portion, or the block portion is for blocking the assembly portion to limit a position of the first body, or to limit the first body to be located at a position at 90 degrees or close to 90 degrees relative to the second body, or to limit the first body to be located at a position at 15 degrees to 150 degrees relative to the second body, or to limit an angle of the first body located at the second body.

11. The assembly structure according to claim 1, being characterized in that, the first body and the assembly portion are combined into a module disposed at the second body, or two ends of an elastic component respectively abut against the first body and the second body or are for the assembly portion to be engaged into another object.

12. The assembly structure according to claim 1, being characterized in that, the first body and the second body are combined into a module by the assembly portion and are disposed at a fixing body, and two ends of an elastic component respectively abut against the first body and the fixing body, or are for the second body to be engaged into another object.

13. The assembly structure according to claim 1, being characterized in that, the assembly portion is vertically assembled or horizontally assembled at the first body or the second body, and an elastic space, a shockproof space, a height adjustment space or a height abutment space is defined between the first body, the second body or the assembly portion by an elastic component or a shockproof component.

14. The assembly structure according to claim 1, being characterized in that, an elastic space, a shockproof space, a height adjustment space or a height abutment space is defined between the first body, the second body or the assembly portion by an elastic component or a shockproof component, or the first body and the second body are respectively assembled at two objects, or for an elastic space, a shockproof space, a height adjustment space or a height abutment space to be present between the objects, or to serve as buffering, position adjustment, height adjustment or height abutment between the objects.

15. The assembly structure according to claim 1, being characterized in that, the assembly portion is vertically assembled or horizontally assembled at the first body or the second body, or an elastic space, a shockproof space, a height adjustment space or a height abutment space is defined between the first body, the second body or the assembly portion by an elastic component or a shockproof component, or the elastic component or the shockproof component causes the first body and the second body to be located at an interval position, a pulled-close position, a height adjustment position or a height abutment position.

16. The assembly structure according to claim 1, being characterized in that, the first body or the second body is provided with an anti-rotation portion, or the anti-rotation portion is for preventing rotation relative to an object, or the anti-rotation portion is for preventing rotation when locked at an object, or the anti-rotation portion is for preventing rotation when locked at an object to further prevent the first body and the second body from a reduced or loosened screw locking force caused by locking torque, or each of the first body and the second body is provided with a corresponding anti-rotation portion for preventing rotation.

17. The assembly structure according to claim 1, being characterized in that, the assembly portion is an extension structure of the first body, and is for mutually interfering, engaging or assembling with an extension structure of the second body, or the assembly portion is an extension structure integrally formed with the first body and is for mutually interfering, engaging or assembling with the extension structure of the second body.

18. The assembly structure according to claim 1, being characterized in that, the first body has a head and a neck for being engagingly connected at an object, or the head passes through an entry portion of the object and is engagingly connected at an engagement receiving portion of the object by the neck, or the first body has a head and a neck for being engagingly connected at an object, or the first body and the second body or the assembly portion have an elastic component or a shockproof component in between, or the first body has a head and a neck for being engagingly connected at an object, or the first body and the second body or the assembly portion have an elastic component or a shockproof component in between to define an elastic space, a shockproof space, a height adjustment space or a height abutment space, or the first body has a shoulder, or the shoulder is for blocking or being pressed, or for a material of the object to flow into or enter a material entry portion of a combining portion of the first body, or the shoulder is for blocking or being pressed, or for a material of the object to be fittingly connected to a combining portion of the first body, or for the first body to be expansion connected at the object.

19. The assembly structure according to claim 1, being characterized in that, the first body, the second body or the object is formed of a metal material, or the first body is formed of a thermal treated metal material or plastic material, or a hardness of the first body is greater than that of the object, or material of the object enters or flows into a material entry portion of the first body when the first body is riveted at and presses the object.

20. The assembly structure according to claim 1, being characterized in that, the assembly portion is riveted or pressed at the first body or the second body for assembly, and a width of the assembly portion is greater than that of an insert portion of the first body so as to interfere with, squeeze or abut against a material for assembly, or the insert portion has a guide portion which guides the assembly portion for assembly.

21. The assembly structure according to claim 1, being characterized in that, the assembly portion passes through the first body and enters the second body for expansion connection and assembly, or wherein an elastic component is comprised, and two ends of the elastic component respectively abut against the second body and the assembly portion, or the assembly portion passes through the first body and enters the second body for expansion connection and stopping at a stop member, or wherein an elastic component is comprised, and two ends of the elastic component respectively abut against the second body and the stop member, or the assembly portion passes through the second body and enters the first body for expansion connection and stopping at a stop member, or the assembly portion passes through the second body and enters the first body for expansion connection and assembly.

22. The assembly structure according to claim 1, being characterized in that, the assembly portion has an engaging portion for engagingly connecting with an object, or the assembly portion has an engaging portion, or the engaging portion is driven by movement of the first body for the engaging portion to be engagingly connected with an engaged object or be disengaged from the engaged object, or the assembly portion has an engaging portion for being driven by rotation of the first body for the engaging portion to be engagingly connected with an engaged object or be disengaged from the engaged object, or the assembly portion has an engaging portion for being driven by rotation of the first body at a first height or a second height, or for the engaging portion to be engagingly connected with an engaged object or be disengaged from the engaged object, or the assembly portion has an engaging portion for being driven by the first body at different positions at a first height or a second height, or for the engaging portion to be engagingly connected with an engaged object or be disengaged from the engaged object.

23. The assembly structure according to claim 1, being characterized in that, the assembly portion has an engaging portion for being driven by movement of the first body and for being engagingly connected with an engaged object or be disengaged from the engaged object, or wherein a fixing body to which the second body is assembled is for being combined at an object, or the engaged portion is disengaged from a casing, or the first body or the second body is pulled or operated to remove a memory or the object from a connector, or the engaging portion is engagingly connected at a casing, or the first body or the second body is pulled or operated to plug/unplug a memory or the object into/from a connector, or the assembly portion has an engaging portion for being driven by movement of the first body and for being engagingly connected with an engaged object or be disengaged from the engaged object, or wherein a fixing body to which the second body is assembled is for being combined at an object, or the engaging portion is disengaged from a casing, or the first body or the second body is pulled or operated to hot-plug a memory or the object into a connector, or the engaging portion is engagingly connected at a casing, or the first body or the second body is pulled or operated to hot-plug a memory or the object into a connector.

24. The assembly structure according to claim 1, being characterized in that, at least one first body, two second bodies and three assembly portions combined with each other are comprised, or at least one first body, two second bodies and three assembly portions are comprised, or wherein each of the first body, two second bodies and two assembly portions has a through hole for mutually combining with the assembly portions, or at least one first body, two second bodies and one assembly portions are comprised, or wherein each of the first body and the two second bodies has a through hole for mutually combining with the assembly portion, or at least one first body, two second bodies and one assembly portion are comprised, or wherein each of the two second bodies has a through hole for mutually combining with the assembly portion.

25. The assembly structure according to claim 1, being characterized in that, the second body has a stop portion for limiting a position of the first body, or the second body has a stop portion for limiting an angle of the first body relative to the second body, or the second body has a stop portion for limiting an angle of the first body to be 15 degrees to 345 degrees relative to the second body.

26. The assembly structure according to claim 1, being characterized in that, the first body has a rotating portion or a moving portion, or the rotating portion or the moving portion is a structure of a sloped surface, an arc surface, a curved surface or a non-right-angle surface or abuts against the second body and the assembly portion by an elastic component, or for the rotating portion or the moving portion to be elastically driven to rotate or move so as to reduce a height of the first body, or the first body has a limiting portion, the limiting portion is for limiting a position of the first body that is rotated, or the second body has an elastic component which for abutting against the limiting portion, or the second body has an elastic component, or the elastic component is for abutting against an intermediator at the limiting portion or for reducing a height of the first body.

27. The assembly structure according to claim 1, being characterized in that, the assembly structure is for being assembled at a heat dissipater, or the assembly structure is a heat dissipater, or the heat dissipater is for dissipating heat of a heat generator, or the heat dissipater has a passage for a cooling fluid to flow through for heat dissipation, or the heat dissipater has an engaging body for being engagingly connected at an object by an engaging body, or the object is provided with a heat dissipater, a printed circuit board, a metal body or a non-metal body, or the second body is a heat dissipater, or the second body and a heat dissipater are formed integrally, or the second body is installed at a heat dissipater.

28. The assembly structure according to claim 1, being characterized in that, the second body has an elastic component which is for abutting against the first body to reduce a height of the first body, or the second body has an elastic component which is for abutting against an intermediator, for the intermediator to abut against the first body or to reduce a height of the first body, or the second body has a setup portion, or is for the assembly portion to be disposed or installed, or the setup portion is a movement space, or the assembly portion moves in the movement space.

29. The assembly structure according to claim 1, being characterized in that, the first body and the second body or the assembly portion have an elastic component or a shockproof element in between, or the first body and the second body or the assembly portion have an elastic component or a shockproof element in between to define an elastic space, a shockproof space, a height adjustment space or a height abutment space, or the first body is assembled at an object, and the second body is assembled at an object, or a distance between the two objects is greater the first body and the second body, or the two objects are not horizontal, or wherein one of the objects is non-planar or has a non-uniform thickness, or the two objects are non-planar and have non-uniform thicknesses, or a distance between the two objects is less than an accumulated height of the first body, the second body and a distance of travel of the elastic component or the shockproof element, or for the first body, the second body, the assembly portion and the elastic component or the shockproof element to perform elastic ascending or elastic descending, or for the two objects to be assembled, or for providing shockproofness for the two objects or shockproofness for one of the objects.
